(19) United States
(12) Patent Application Publication
(10) Pub. No.: US 2024/0087838 A1
(43) Pub. Date: Mar. 14, 2024

(54) MULTI-BEAM MICROSCOPE AND METHOD FOR OPERATING A MULTI-BEAM MICROSCOPE USING SETTINGS ADJUSTED TO AN INSPECTION SITE

(71) Applicant: Carl Zeiss MultiSEM GmbH, Oberkochen (DE)

(72) Inventor: Stefan Schubert, Oberkochen (DE)

(21) Appl. No.: 18/501,863

(22) Filed: Nov. 3, 2023

Related U.S. Application Data
(63) Continuation of application No. PCT/EP2022/061042, filed on Apr. 26, 2022.

(30) Foreign Application Priority Data
May 27, 2021 (DE) 10 2021 205 394.7

(51) Int. Cl. H01J 37/153; H01J 37/244; H01J 37/28

(52) U.S. Cl. CPC H01J 37/153; H01J 37/244; H01J 37/28; H01J 2237/24465; H01J 2237/24495; H01J 2237/24521; H01J 2237/24528; H01J 2237/24542; H01J 2237/24578; H01J 2237/24592; H01J 2237/2806; H01J 2237/2817

(57) ABSTRACT

Multi-beam effects which reduce the accuracy, or the speed of a wafer inspection are corrected dependent on an inspection position using an improved multi-beam system and a wafer inspection method using the multi-beam system. The multi-beam system comprises a mechanism for influencing and homogenising an extraction field dependent on the inspection position, for example dependent on a distance from a wafer edge.

### CROSS-REFERENCE TO RELATED APPLICATIONS

The present application is a continuation of, and claims benefit under 35 USC 120 to, international application PCT/EP2022/061042, filed Apr. 26, 2022, which claims benefit under 35 USC 119 of German Application No 10 2021 205 394.7, filed May 27, 2021. The entire disclosure of each these applications is incorporated by reference herein.

### FIELD

The disclosure relates to multi-beam microscopes and methods of operating such microscopes. In some embodiments, the methods comprise using a multi-beam microscope using settings adjusted to an inspection site.

### BACKGROUND

With the continuous development of ever smaller and ever more complex microstructures such as semiconductor components, there is often a desire to develop and optimize planar production techniques and inspection systems for producing and inspecting small dimensions of the microstructures. By way of example, the development and production of the semiconductor components typically involves monitoring of the design of wafers, and the planar production techniques typically involve process monitoring and process optimization for a reliable production with a high throughput. Moreover, there have been recent desires for an analysis of semiconductor wafers for reverse engineering and for a customer-specific, individual configuration of semiconductor components. Therefore, it can be desirable to provide a mechanism for inspection which can be used with a high throughput for examining the microstructures on wafers with great accuracy. Typical silicon wafers used in the production of semiconductor components have diameters of up to 300 mm. Each wafer is often subdivided into 30 to 60 or more repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure sizes of the integrated semiconductor structures in this case can extend from a few micrometres (μm) to the critical dimensions (CD) of 5 nanometres (nm), wherein the structure dimensions will become even smaller in the near future; in future, structure sizes or critical dimensions (CD) are expected to be less than 3 nm, for example 2 nm, or even under 1 nm. In the case of the small structure sizes, it is generally desirable to relatively quickly identify defects of the size of the critical dimensions in a relatively large area. For several applications, the desired properties for the accuracy of a measurement provided by an inspection device can be even higher, for example by a factor of two or one order of magnitude. By way of example, it is often desirable to measure a width of a semiconductor feature with an accuracy of below 1 nm, for example 0.3 nm or even less, and to determine a relative position of semiconductor structures with a superposition accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or raster. By way of example, 4 to 10 000 individual electron beams can be provided as primary radiation, with each individual electron beam being separated from an adjacent individual electron beam by a pitch of 1 to 200 micrometres. By way of example, an MSEM has approximately J=100 separated individual electron beams (“beamlets”), which for example are arranged in a hexagonal raster, with the individual electron beams being separated by a pitch of approximately 10 μm. The plurality of J individual charged particle beams (primary beams) are focused on a surface of a sample to be examined by way of a common objective lens. By way of example, the sample can be a semiconductor wafer which is accommodated via a wafer chuck that is assembled on a movable stage. During the illumination of the wafer surface with the primary individual particle beams, interaction products, for example secondary electrons or backscattered electrons, emanate from the surface of the wafer. Their start points correspond to those locations on the sample on which the plurality of J primary individual particle beams are focused in each case. The amount and the energy of the interaction products depends on the material composition and the topography of the wafer surface. The interaction products form a plurality of secondary individual particle beams (secondary beams), which are collected by the common objective lens, and which are directed by a projection imaging system of the multi-beam inspection system at a detector arranged in a detection plane. The detector comprises a plurality of detection regions, each of which comprises a plurality of detection pixels, and the detector measures an intensity distribution for each of the J secondary individual particle beams. A digital image of an image field of for example 100 μm×100 μm is obtained in the process.

Certain known multi-beam electron microscopes comprise a sequence of electrostatic and magnetic elements. At least some of the electrostatic and magnetic elements are adjustable in order to adapt the focus position and the stigmation of the plurality of charged individual particle beams. Such a multi-beam system with charged particles moreover can comprise at least one crossover plane of the primary or the individual secondary charged particle beams. Moreover, the system can comprise detection systems to make the setting easier. The multi-beam particle microscope can comprise at least one beam deflector (“deflection scanner”) for collective scanning of a region of the sample surface via the plurality of individual primary particle beams in order to completely sweep over the image field of the sample surface with the plurality of the primary beams. Moreover, such a system from can comprise a beam splitter arrangement which is configured such that the bundle of primary beams is guided from the generation device of the bundle of primary beams to the objective lens, and the bundle of secondary beams is guided from the objective lens to the detection system. Further details regarding an example of a multi-beam electron microscope and a method for operating same are described in the PCT application PCT/EP2021/061216, filed on 29 Apr. 2021, the disclosure of which is incorporated in full here within by reference.

In the case of scanning electron microscopes for wafer inspection, it is often desirable to keep the imaging conditions stable such that the imaging can be carried out with great reliability, great imaging fidelity and high repeatability. The throughput generally depends on a plurality of parameters, for example the speed of the displacement stage and of the realignment at new measurement sites, and the area measured per unit of capture time. The latter is determined, inter alia, by the dwell time on the pixel, the pixel size and the number of individual particle beams. Additionally, time-consuming image postprocessing may be involved for a multi-beam electron microscope; by way of example, the signal generated from charged particles by the detection system of the multi-beam system are often digitally corrected before the image field from a plurality of image sub-fields or sub-fields is put together (“stitching”).

Previous methods may not longer be sufficient in all cases, such as in the case of inspecting semiconductors using a multi-beam microscope and the high demands on the measurement accuracy connected therewith. A number of special effects which can reduce the desired high measurement accuracy occur when semiconductors are inspected. The complex effects relate to the raster arrangement of the plurality of charged particle beams and a different shape or size of individual particle beams from the plurality of charged particle beams. By way of example, some of these effects do not occur in the case of biological samples or cannot be observed there. Other effects are sometimes so small that they might only play a role in the case of the semiconductor inspection with the increased measurement accuracy of better than 2 nm or better than 1 nm. The effects can reduce the resolution or the signal strengths during the wafer inspection. Moreover, the measurement accuracy of dimensions or distances of structures on wafer surfaces, for example, can be adversely affected when these effects occur. In principle, some of these effects can be at least partly compensated by a change in the settings of the multi-beam microscope. However, certain previous methods for determining and setting a best setting of the multi-beam microscope for the purposes of avoiding the unwanted effects can be too slow or too complicated for a wafer inspection task with a high throughput. By way of example, a previous method for determining and setting a best focal plane of the multiplicity of the primary beams can have a negative effect on the throughput. U.S. Pat. No. 10,388,487 describes a determination of object properties in a first measurement with first setting parameters and a derivation of second setting parameters resulting therefrom in order to measure the object therewith in a second measurement. Beam properties such as the focal position and stigmation, for example, are determined from the object properties. However, this method can reduce the throughput since a second, improved measurement is preceded by a first measurement with a high resolution. U.S. Pat. No. 10,535,494 describes a detection system used to determine the beam shape of secondary beams, but not the raster arrangement of the beams itself. DE 10 2018 124 044 B3 describes a detection system that it is believed can only correct relatively small effects of local sample charging by assigning the plurality of secondary electron beams to detector channels. For a measurement accuracy of better than 2 nm or better than 1 nm, only considering the detection system and the secondary particle path may no longer sufficient.

A multi-beam system can provide a higher throughput, and there can be the occurrence of complex effects that relate to the plurality of beams of charged particles, for example the raster arrangement of the plurality of charged particle beams or a different shape or size of individual particle beams. According to certain known multi-beam systems and methods for operating a multi-beam system, these complex effects can involve complicated analysis and adjustment of the multi-beam system, which can significantly reduce the throughput of the multi-beam system.

### SUMMARY

There are increasing demands on throughput/speed and on precise measurement of ever smaller structures, and it is believed that it would be desirable to improve the existing multi-beam systems and methods for operating a multi-beam system. This can apply, for example, to the inspection of polished wafer surfaces with HV structures. Thus—even under the not entirely realistic assumption of a lack of system drift and the like—it may no longer sufficient to set the multiple electron microscope at a predefined working point with an associated working distance using the methods from the prior art.

It is believed that the complex multi-beam effect of the plurality of primary beams cannot be determined directly without effort. An occurrence of a complex multi-beam effect of the primary beams, for example a distortion of the raster arrangement of the primary beams, a magnification difference of the raster arrangement of the primary beams or a deviation in the shape and size of focal points of the primary beams, can lead to defective imaging, for example to incorrect positioning of the images of surface structures of a wafer, or to an incorrect measurement of dimensions or areas of surface structures. If there is a significant occurrence of a complex multi-beam effect of the primary beams, this may furthermore lead to the expected drop in the signal strength of the secondary particles, right up to a complete loss of the signal strength of the secondary particles. Especially if the known methods for fast adjustment of the detection path are applied and thus compensate the complex multi-beam effect of the primary beams for the purposes of keeping the signal strength of the secondary particle highs, the effect of incorrect imaging of the object remains. However, especially in the case of wafer inspection, the positions and dimensions of surface structures are relevant and have to be determined with high precision of less than 2 nm, ideally less than 1 nm or even less.

The present disclosure seeks to provide an improved multi-beam system and an improved method for operating a multi-beam system, by which complex effects, such as those discussed above, are reduced or compensated without the throughput of a wafer inspection being reduced in the process.

The disclosure also seeks to provide a multiple particle beam system that operates with charged particles and an associated method for operating same with a high throughput, which facilitates a highly precise measurement of semiconductor features with a resolution of below 4 nm, below 3 nm or even below 2 nm.

The disclosure provides an improved multi-beam system and improved method for operating a multi-beam system, by which complex multi-beam effects that occur during the interaction of a plurality of beams of charged particles with a wafer surface are compensated. According to an embodiment of the disclosure, the complex multi-beam effects can be characterized by a combination of a distortion of the plurality of secondary beams and a change in the size and shape of the focal points on a detector. According to a further embodiment, a complex multi-beam effect occurs in particular in the vicinity of an edge of the wafer or in the vicinity of a preceding inspection position, or the size of the one complex multi-beam effect depends directly on a distance of an inspection site from an edge of the wafer or a preceding inspection position. For the compensation there is a characterization or classification of the complex multi-beam effects and a derivation of measures, for example an adjustment of the primary or illumination path and an adjustment of the secondary or detection path. According to this derivation of measures, parameters for setting or adjusting primary and secondary paths are derived, which are suitable for counteracting the complex effects. Moreover, a multi-beam system may comprise a mechanism in the direct vicinity of the wafer or the wafer surface which is suitable for minimizing or compensating a complex multi-beam effect. Using this mechanism, an electric field between the wafer surface and a last electrode of an objective lens of the multi-beam system is influenced, the field simultaneously acting on the primary particle beams and the secondary particle beams.

The multi-beam system and the methods for operating the multi-beam system of the present disclosure solve the problem of fast wafer inspection with a great imaging fidelity by virtue of a complex multi-beam effect of the primary beams and the secondary beams being determined at an inspection site and measures being carried out for compensating the complex multi-beam effect by way of changing parameters, both of components of the illumination system and of the detection system. In particular, this is facilitated during a routine inspection of wafers being always similar in principle, and similar multi-beam effects with similar causes are always occurring.

In an embodiment, the complex multi-beam effect of the primary beams is determined by a time-averaged measurement of the raster arrangement of the plurality of secondary beams and the shape or size of at least one focal point of a secondary beam. In this case, influence of the surface structuring of the semiconductor wafer on the measurement signal is reduced by time averaging. An analysis of the raster arrangement of the plurality of secondary beams and the shape or size of at least one focal point of a secondary beam is used to deduce the probable complex multi-beam effect of the primary beams and correction measures for the illumination path are introduced. In this case, the method of the measurement can be repeated. It is consequently possible within the scope of the wafer inspection to determine a complex multi-beam effect of the primary beams at an inspection position on the surface of a structured wafer purely from determining the accumulated complex multi-beam effect of the secondary beams without having to use a reference object. As a result of the time averaging of the measurement, the measurement can be carried out very quickly here, for example by way of very quickly scanning the object surface at the inspection position using the plurality of primary beams.

In a further embodiment, the complex multi-beam effect of the primary beams is determined from a priori information. Further, it was found that some complex multi-beam effects depend on the inspection position on a wafer surface, in particular on the distance of an inspection position from an edge of the wafer or a preceding inspection position. Since the inspection positions on a wafer are known in advance, this dependence can be used in accordance with one embodiment of the disclosure to compensate the complex multi-beam effects. By way of example, the parameters for driving the multi-beam system may depend on the inspection position known in advance. By way of example, a sequence of inspection tasks can be modified in order to reduce effects of preceding inspection positions. In a further embodiment, an edge effect caused by an inhomogeneous extraction field is reduced by additional electrodes in the periphery of a wafer reception area. During inspection, correction voltages are applied to the additional electrodes. In one example, an extraction field is set by way of a counter electrode, formed by a plurality of differently driveable electrode segments, so that a complex multi-beam effect is reduced.

In principle, the method of determining the complex multi-beam effect can also be carried out during an inspection task. Consequently, it is also possible to detect changeable complex multi-beam effects of the primary beams, or unexpected deviations of the primary beams.

According to a first embodiment of the disclosure, the improved multi-beam system comprises a spatially resolving detection device which is configured to detect focal points of a plurality of secondary beams during an inspection task, independently of a surface contrast of a wafer surface at an inspection position. Further, the improved multi-beam system comprises a control unit having a memory and a computing unit which is configured to determine a current raster arrangement of the focal points of the plurality of primary beams from the focal points of the plurality of secondary beams and to determine a deviation from a predefined raster arrangement using this current raster arrangement. According to an embodiment, the control unit is further configured to determine at least one current shape and size of a predetermined focal point of the plurality of secondary beams. By way of example, a differing shape or size of at least two focal points of the plurality of secondary beams is determined. The control unit is further configured to analyse the deviation of the current raster arrangement from a predefined raster arrangement and use this to deduce the occurrence of a certain complex multi-beam effect of the primary beams. According to an embodiment, the control unit determines a deviation of the current shape and size of the at least one predetermined focal point from a predetermined shape and size of the focal point. Further, the control unit is configured to determine a possible cause for the complex multi-beam effect of the primary beams. In an example, the control unit determines a plurality of possible causes for the complex multi-beam effect of the primary beams, sorted according to their occurrence probability. In an example, during the determination of the possible cause for the complex multi-beam effect, a machine learning algorithm is applied. The machine learning algorithm can be trained by a growing set of frequently occurring complex multi-beam effect with frequently occurring causes, for example a vicinity to a previous inspection position or a proximity to an edge of a wafer.

The control unit is further configured to determine measures for adjusting the illumination path and the detection path of the multi-beam system according to the most likely cause of the complex multi-beam effect at an inspection position. A plurality of control parameters are determined within the scope of this determination, the parameters being used to drive or set components within the illumination path and within the detection path of the multi-beam system. These parameters may also be changes in relation to already set parameter values at certain components of the illumination path or detection path of the multi-beam system. Possible components include a quasi-static deflector for the plurality of beams of charged particles, a dynamic deflector for the scanning deflection of the plurality of beams of charged particles, electrostatic or magnetic lenses with changeable focusing effects for the plurality of beams of charged particles, multi-pole elements and energy filters for the plurality of beams of charged particles, or else array components, by which each individual beam of the plurality of beams of charged particles can be influenced. In an example, the adjustment mechanism can comprise for example the parameters for setting a homogeneous extraction field between the object surface and an objective lens system of the multi-beam system.

In an embodiment, the control unit is connected to a unit for image evaluation and configured to provide a correction signal to the unit for image evaluation for the purposes of correcting at least a part of the complex multi-beam effect, for example by image processing. The unit for image evaluation is connected to a detection unit of the multi-beam system and is configured to carry out a correction of the image information of the detection unit using the correction signal. By way of example, a distortion known with great accuracy, a perspective distortion or a magnification aberration of the raster arrangement of the plurality of primary beams can be compensated by digital image processing in a downstream image evaluation. By way of example, a positional deviation of individual primary beams can be taken into account when putting together (“stitching”) the individual images.

The multi-beam system comprises a displacement stage with an object holder for the semiconductor wafer, the object holder being suitable for receiving and positioning the wafer below the objective lens of the multi-beam system. To this end, the object holder comprises a reception area or wafer chuck for receiving the substantially planar wafer with a thickness T and an external diameter D. The reception area for the wafer comprises electrical contacts to the control unit in order to apply a voltage difference between an electrode system of the multi-beam system and the wafer. The electrode system is situated below the objective lens or is part of the objective lens and comprises electrical contacts to the control unit. The control unit is configured to supply suitable voltages to the electrode system and the wafer surface during operation, in order to build up, between the wafer surface and the electrode system, an electric field profile of an extraction field perpendicular to the wafer surface with equipotential lines parallel to the wafer surface during operation. This field is referred to as the extraction field.

For an inspection task without complex multi-beam effects, it can be desirable, for example, for the extraction field to have a homogeneous form and to form a constant predefined electric field strength on the wafer surface over an inspection position. Attempts are therefore made to generate by way of the voltage difference an extraction field that is as homogeneous as possible. However, inhomogeneities of the extraction field occur, in particular in the vicinity of an edge of a wafer. This complex multi-beam effect is also referred to as edge effect or boundary effect. In a second embodiment, the object holder further comprises a ring-shaped correction electrode with a height DE above the reception area, the correction electrode being arranged in the periphery of the reception area and having an internal diameter DI>D such that when the wafer is received, a constant distance G is formed in each direction between the edge of the wafer and the ring-shaped electrode. The ring-shaped electrode is insulated with respect to the reception area and electrically connected to the control unit such that a voltage difference relative to the voltage of a wafer arranged on the reception area can be applied to the ring-shaped electrode during operation. The control unit of the multi-beam system is configured during operation to supply a first voltage to the reception area and the wafer arranged thereon and supply a second voltage to the ring-shaped electrode for reducing an edge effect, for the purposes of generating the homogeneous extraction field.

In a third embodiment, the aforementioned electrode system is formed by a plurality of for example two, four, eight or more electrodes which are insulated from one another and are each electrically connected to the control unit. The control unit is configured during operation to supply different voltages to the plurality of electrodes in order to generate a homogeneous extraction field at an inspection position during operation. Since measurements are only carried out at one inspection position at any one time, it is advantageous to vary the voltage of at least one segment of the ring electrode dependent on the inspection position.

Many effects related to imaging with a multi-beam microscope are linked very strongly to the topological conditions. By way of example, the edge of a wafer has a significant influence during the wafer inspection. Since the relative position of the inspection positions with respect to the edge of the wafer is known in advance in the context of the wafer inspection in particular, the improved adjustment of both the detection path and the illumination path dependent on a distance of an inspection position from an edge of the wafer can already be implemented when homing in on the inspection site. In the fourth embodiment, a multi-beam system and a method for operating the multi-beam system are provided, within the scope of which parameters of components of the illumination path and of the detection path of the multi-beam system are set dependent on a distance of an inspection position from an edge or boundary of the wafer. To this end, the multi-beam system comprises a control unit which determines the distance of an inspection position from an edge or boundary of the wafer. The control unit determines a complex multi-beam effect from the distance and the current working point of the multi-beam system. Further, the control unit is configured during the operation of the multi-beam system at the inspection position to drive components of the illumination path and of the detection path of the multi-beam system with parameters which are suitable for reducing or completely avoiding the complex multi-beam effect. One embodiment of the method contains the acquisition and storage of parameters of an improved adjustment of the detection path and illumination path for different inspection sites dependent on a distance from an edge of the wafer. Then, the optimal parameters of an improved adjustment of both the detection path and the illumination path are determined and set dependent on a next inspection site from the predetermined and stored parameters during a wafer inspection.

It was found that a number of further complex multi-beam effects depend on the inspection position on the surface of a wafer and are therefore, in principle, known in advance. In the fifth embodiment, a multi-beam system and a method for operating the multi-beam system are provided, within the scope of which parameters of components of the illumination path and of the detection path of the multi-beam system are set dependent on a priori information. In one example, the multi-beam system comprises a control unit to this end, which control unit determines the composition of the object, at least at an inspection position, prior to measurement or inspection at the inspection position. In this case, the determination of the composition of the object comprises a determination of the material composition of the object, for example from CAD information about the semiconductor structures formed in a wafer at the inspection position. On the basis of the composition there is a determination of expected complex multi-beam effects and a setting of parameters of the multi-beam system which are suitable for reducing or completely avoiding the complex multi-beam effect. In an alternative example, the a priori information consists of information from earlier inspections at similar inspection sites, for example on other wafers. In an example, the method contains storing a dynamic correction dependent on an identical inspection position during the sequential inspection of a plurality of wafers.

It was found that a number of further complex multi-beam effects depend on adjacent inspection position on the surface of a wafer and are therefore, in principle, known in advance. In the sixth embodiment, a multi-beam system and a method for operating the multi-beam system are provided, within the scope of which parameters of components of the illumination path and of the detection path of the multi-beam system are set dependent on adjacent inspection positions. In one example, the multi-beam system comprises a control unit to this end, which control unit determines for example a current charge distribution of the object at an inspection position caused by preceding inspections on the same object, prior to measurement or inspection at the inspection position. On the basis of the current charge distribution there is a determination of expected complex multi-beam effects and a setting of parameters of the multi-beam system which are suitable for reducing or completely avoiding the complex multi-beam effect. A special example is formed by a method of repeatedly homing in on the same inspection position on the same wafer.

The methods and the multi-beam microscope designed for the application of the methods according to the embodiments facilitate an improved adjustment of both the detection path and the illumination path for a specific inspection position on a surface of an object. According to the seventh embodiments, a method is based on the basis of acquiring and evaluating two fundamentally different information items about the multi-beam microscope and the interaction with an object. Firstly, the raster arrangement of the plurality of secondary beams is detected and evaluated. Secondly, the shape and size of the at least one focal point of the secondary beams is detected and evaluated. It is also possible to evaluate shapes and sizes of a plurality of focal points, for example of at least three focal points, of the secondary beams.

Both information items are acquired during scanning imaging of a portion of a surface of an object. In this case, a plurality of J focal points of J primary beams are moved in scanning fashion over the surface of the object and a plurality of J scan positions on the object surface are illuminated at the same time. To this end, a first deflection unit for scanning deflection of the plurality of J primary beams is situated in the primary path or illumination path. Each incidence location of the J focal points of the J primary beams forms a source location for secondary electrons, which are collected and imaged on a detector, during the short period of time of scanning irradiation using the J primary beams. The plurality of the J source locations of the secondary electrons move synchronously over the object surface in accordance with the scanning irradiation using J primary beams. Therefore, a second deflection unit for scanning deflection of the J secondary beams that emanate from the J source locations is situated in the imaging path of the secondary electrons, which is also referred to as detection path or secondary path, so that the focal point of the J secondary beams on the detector remain at J same detection locations. In this case, the second deflection unit in the secondary path is synchronized with the first deflection unit in the primary path.

A plurality of J time-sequential data streams which are converted into a plurality of J two-dimensional digital image information items are acquired as a result of the scanning illumination with the plurality of J primary beams and the acquisition of the signals of the plurality of J secondary beams synchronously with the scanning illumination. Each image information item represents the spatially resolved rate of generation of secondary electrons by the spatially resolved illumination of the object surface by a focal point of a primary beam. In this case, the rate of the generation of secondary electrons depends on the local surface condition, for example the local material composition of a structured wafer surface. The information about the shape and size of the focal points themselves and the raster arrangement of the focal points for adjusting both the detection path and the illumination path are acquired in time-averaged fashion such that the influence of the structuring on the object surface is reduced by averaging over a plurality of scan positions on the surface. However, the measurement can also be implemented on a completely unstructured wafer or an unstructured test object. Consequently, the method is rendered possible for a plurality of objects, and there is no need for special measurement or calibration objects. In particular, the method of adjusting both the detection path and the illumination path may also be implemented during an inspection task at an inspection position on an object surface.

By way of example, this therefore also allows the method of adjusting both the detection path and the illumination path to be used for a fast autofocus. In general, this allows the method of adjusting both the detection path and the illumination path to be used for a dynamic correction. In respect of a dynamic correction, reference is made to the PCT patent application PCT/EP2021/061216, filed on 29 Apr. 2021, which as a result is included in full in the disclosure by reference.

Determining the parameters of an improved adjustment of both the detection path and the illumination path dependent on an inspection site is implemented iteratively in an example. Initially, an image is recorded without corrections or changes in the parameters. The deviation of the raster arrangement of the plurality of secondary beams from a predefined or expected raster arrangement is detected and evaluated, and the deviation of the shape and size of at least one focal point from a predefined or expected shape and size of the focal point is detected and evaluated at the same time. As described above, the deviations are detected within the scope of time averaging during the scanning of the object surface with a plurality of primary beams in order to eliminate influences of the composition of the wafer. A probable cause for the deviation is determined from the deviations, and suitable parameters are determined for the adjustment of the illumination path and detection path. The detection of the various deviations, specifically the deviation of the raster arrangement of the plurality of secondary beams and of the shape and size of the focal points, allows more targeted conclusions to be drawn about the cause, for example whether there is a disruption or error in the illumination path and a deviation of the plurality of focal points of the primary beams is already present on the wafer surface or whether an edge or topography of the wafer is a cause for the deviation, whether global or local charging effects are present, or whether there is a disruption in the detection path.

A compensation of the complex multi-beam effect is determined in accordance with a model following the analysis of the raster arrangement and the complex multi-beam effect. In general, the success of the compensation can be verified at a sample site, for example of a reference sample, and a fine correction can be carried out. The model for calculating the compensation can be improved by the fine correction.

Further information, for example from additional detectors or a priori information, can be used to carry out the determination of the most probable cause for the deviations with even greater accuracy. Further detectors may comprise a distance sensor for determining the distance of the sample surface from a reference area. The use of such a distance sensor for example allows a better distinction to be made between global charging of the object and purely mechanical defocusing. Further examples comprise field sensors for measuring an electric or magnetic field strength in the vicinity of the object surface. A priori information may comprise CAD information about the inspection position, or stored information from earlier measurements on similar objects or at similar inspection sites. By way of example, possible inhomogeneous or local charging effects of the object may be determined from CAD information. By way of example, regions of a wafer may be conductively connected and scatter charging effects beyond an inspection site. By way of example, regions of a wafer may comprise capacitances which store charging effects over a relatively long period of time.

In general, the position of the inspection site in relation to the sample edge is also an information known in advance. Consequently, it is possible to take account of distortions of the raster arrangement by way of edge effects and distortions as a result of inhomogeneous charging. Preceding measurements form further a priori information. By way of example, charges may arise due to preceding measurements and may only dissipate slowly by way of leakage currents. The charging of already scanned, adjacent inspection sites lead to distortions in the raster arrangement and this a priori information may be considered when determining the cause for the deviations.

In principle, one may already compensate a compensation of a complex multi-beam effect in advance, for example when homing in on an inspection position. Once the probable cause of the deviations has been determined, it is possible to implement correction measures or an adjustment of the detection path and illumination path. Then, the determination of the deviations is repeated. Should the deviations lie within a predetermined tolerance range, the portion of the object surface at the inspection site is measured or imaged in a next step. Should the deviation still exceed a predetermined tolerance limit, determining the cause and determining new parameters for adjusting the detection path and illumination path is repeated. By way of example, a fine correction is determined and carried out in a second step.

The causes of the deviations of the raster arrangement and of the shape and size of beam focal points may be subject to a dynamic change. By way of example, global charging of a sample increases when the illumination by the plurality of primary beams increases and may lead to an increasing deviation of the raster arrangement while imaging. Such dynamic effects are determined in an eighth embodiment of the disclosure and for example the speed of a change or deviation of the raster arrangement and of the shape and size of beam focal points is taken into account. This allows the deviations of the raster arrangement and of the shape and size of beam focal points to be corrected dynamically and allows the parameters for adjusting the detection path and illumination path to be dynamically altered in predetermined fashion during the capture of an image portion of the object surface.

In a ninth embodiment a multi-beam system for inspecting wafers contains a first and a second electron detector and a beam deflector for deflecting the secondary electron beams from the first to the second electron detector. The first electron detector can detect the plurality of J secondary electron beams during an inspection task, the object contrast of a wafer with a high data rate and with little noise. The second electron detector can detect the raster arrangement and the shape or size of the focal points of the plurality of J secondary electron beams with a high spatial resolution, time-averaging of the signal over a plurality of scanning points on the surface of the wafer being implemented at the same time in order to suppress an object contrast. As a result, a complex multi-beam aberration can be determined very quickly during an inspection task and optimal parameters for a complex multi-beam system can be set. From the analysis and evaluation of the raster arrangement and the shape and size of the focal points of the secondary electrons, it is possible to deduce properties of the illumination system, the detection system or the inspection position on the wafer.

In general, a multi-beam system according to the disclosure can be configured in such a way that it is configured to quickly carry out an inspection task in relation to a surface of a wafer in a first setting, and configured to detect a complex multi-beam aberration in a second setting. In this case, a complex multi-beam aberration is given by a deviation of the raster arrangement of the plurality of particle beams and the deviation of the shape and size of at least one focal point of a particle beam. In an example, the complex multi-beam aberration is given by a deviation of the raster arrangement of the plurality of particle beams and the deviation of the shape and size of the focal points of at least three secondary beams on a detector. In a second setting, the complex multi-beam aberration is detected by way of time averaging over a plurality of raster points on the wafer surface, as a result of which an object contrast is averaged. Consequently, it is possible to quickly switch between an inspection task and the detection of the complex multi-beam aberration, and a high throughput is obtained. In some embodiments the multi-beam system according to the disclosure is configured such that a complex multi-beam aberration is detected while an inspection task in relation to a surface of a wafer is carried out quickly. The complex multi-beam aberration is detected by way of time averaging over a plurality of raster points on the wafer surface, as a result of which an object contrast is averaged. Consequently, an inspection task and the detection of the complex multi-beam aberration can be implemented simultaneously, and a high throughput is obtained.

A multi-beam system according to the disclosure has available a plurality of primary particle beams and a plurality of secondary particle beams, and comprises a spatially resolving detector, at least one deflection system for deflecting the plurality of primary and secondary particle beams for the purposes of collective scanning of a portion of a structured surface of a wafer, and a control device for driving the detector and the deflection system, the control device and the detector being designed to capture a time-averaged inspection image of a raster arrangement of the plurality of secondary particle beams and/or capture a digital image of the portion of the structured surface with a spatial resolution of 2 nm, 1 nm or less. The control device is configured, in a first mode of operation for capturing the time-averaged inspection image of the raster arrangement, to quickly scan a plurality of the primary particle beams over the portion of the structured surface of the wafer in a time T1 using the deflection system and, in a second mode of operation for recording the digital image of the portion of the structured surface, to slowly scan the plurality of primary particle beams over the portion of the structured surface of the wafer in a time T2 using the deflection system, where T1<T2, such as T1<T2/10, for example T1<T2/100. The detector can contain a first detector and a second detector and the multi-beam system can comprise a detection unit having a beam deflector which is driven by the control unit and configured to deflect the plurality of secondary particle beams either onto the first detector or on the second detector during operation. The beam deflector can additionally be configured to keep the plurality of secondary particle beams at a constant position either on the first detector or on the second detector during operation. In an alternative example, the detector can be designed for the simultaneous capture of the time-averaged inspection image of the raster arrangement of the plurality of secondary particle beams and of the digital image of the portion of the structured surface with a high spatial resolution with a pixel dimension of 2 nm, 1 nm or less. To this end, the detector may contain an electron conversion element which generates photons from electrons, and photons are detected simultaneously using a first, fast light detector for capturing a portion of the wafer surface and a second, slow light detector for capturing the inspection image of the raster arrangement.

In an example, the control device is further configured to determine a complex multi-beam effect consisting in a change in the incidence locations of the plurality of particle beams and a change in the shape and size of the focal points of the particle beams from the inspection image of the raster arrangement, and to derive and set changes in the setting parameters of the multi-beam system on the basis of the complex multi-beam effect. In an example, the control device is connected to a plurality of components of an illumination path and of a detection path, including components for setting a homogeneous extraction field, and is configured to suitably adjust parameters of the components of the illumination path and of the detection path, including components for setting a homogeneous extraction field, for the purposes of reducing the complex multi-beam effect.

A multi-beam system according to an embodiment contains the following components which are connected to the control device for driving purposes:
a quasi-static deflector for the plurality of primary particle beams,
a dynamic deflector for the scanning deflection of the primary particle beams and the secondary particle beams,
a dynamic deflector for the scanning deflection of the secondary particle beams,
electrostatic or magnetic lenses with a changeable focusing effect,
a raster arrangement of multi-pole elements for influencing the primary particle beams,
correction electrodes for setting a homogeneous extraction field between the wafer surface and a counter electrode of an objective lens system of the multi-beam system. In an example, the multi-beam system can further comprise a mechanism for generating a homogeneous extraction field in the edge region of a wafer, the mechanism comprising electrical contacting of the counter electrode below the objective lens or of a part of the objective lens for the purposes of supplying a first voltage difference V1 during operation. Further, the mechanism can comprise a reception area for receiving and positioning a wafer below the objective lens, with electrical contacting of the reception area for the purposes of applying a second voltage difference V2 to the wafer during operation. Further, the mechanism can comprise at least one correction electrode arranged in the periphery of the reception area and having electrical contacts for the purposes of supplying at least one third of voltage difference V3 during operation.

In an example, the control unit of the multi-beam system further comprises a unit for image evaluation. Then, the control unit is configured to drive the unit for image evaluation with a correction signal for the purposes of correcting at least one part of the complex multi-beam effect.

In an embodiment, the wafer inspection multi-beam system comprises a displacement stage for receiving a wafer, a spatially resolving detector, a first deflection system for deflecting the plurality of primary particle beams for the purposes of collective scanning of a portion of a structured surface of the wafer, and a second deflection system for deflecting the plurality of secondary particle beams in order to keep the focal points of the secondary particle beams on the detector constant. Further, the multi-beam system contains a control device, the control device being configured to acquire a list of inspection tasks at a plurality of inspection positions and to work through the list, and the control device further being configured to set the setting parameters of components of the illumination path and of the detection path, including components for setting the homogeneous extraction field, for the purposes of reducing a complex multi-beam effect at an inspection position. To this end, the control unit is configured to detect the distance of an inspection position from an edge of the wafer and to compensate a complex multi-beam effect caused by the wafer edge. The control unit can be further configured to determine the composition of the wafer at an inspection position from CAD data prior to a measurement or inspection at the inspection position, and to compensate a complex multi-beam effect caused by the composition. To this end, the control unit comprises a memory and can determine stored parameters from stored inspection tasks at similar inspection sites and can set these for the purposes of reducing a complex multi-beam effect at an inspection position. The control unit can determine parameters from preceding inspection tasks at adjacent inspection sites and can set these for the purposes of reducing a complex multi-beam effect at an actual or subsequent inspection position. The control unit may change a scanning program for driving the first and second deflection systems in order to at least partly compensate a complex multi-beam effect, the control unit further being configured to change a scanning program for driving the first and second deflection systems in order to at least partly compensate a complex multi-beam effect.

A method of wafer inspection using a multi-beam system includes homing in on an inspection position on a wafer and, on the basis of the inspection position, determining the setting parameters of the multi-beam microscope, determined in advance, for optimal imaging at the inspection position. The determined setting parameters are set and an image is taken of a portion of the surface of the wafer at the inspection position. The setting parameters of the multi-beam system may be determined from predefined setting parameters assigned to the inspection position or the setting parameters for optimal imaging at the inspection position can be determined from at least two setting parameters assigned two adjacent inspection positions. Additionally or alternatively, optimized setting parameters may be determined from a priori information about the inspection position. A priori information may contain the distance of the inspection position from an edge of the wafer or from preceding image recordings at preceding inspection positions, or CAD information about the material composition at the surface of the wafer at the inspection position. The setting parameters comprise voltage values for generating a homogeneous extraction field at the surface of the wafer, for example the voltage values being supplied to electrodes.

The disclosure is not restricted to the specific embodiments, but variations of the embodiments are also possible. Although in principle reference is made to a wafer as an object, the disclosure is also applicable to other objects as used in semiconductor manufacturing. By way of example, the object can also be a mask, for example a mask for EUV lithography, rather than a semiconductor wafer. In contrast to semiconductor wafers, such masks are generally rectangular and have a significantly greater thickness. By way of example, in this case the electrode around the object reception area does not have a ring-shaped embodiment but a rectangular embodiment. The disclosure is further described on the basis of a multi-beam system having a plurality of primary electron beams, but other charged particles, for example helium ions, may also be used.

The described embodiments of the disclosure can be combined with one another in full or in part, provided that no technical contradictions arise as a result. It is self-evident that a person skilled in the art considers obvious variations of the exemplary embodiments to be possible and not excluded in the description.

The disclosure will be understood even better with reference to the accompanying figures, in which:

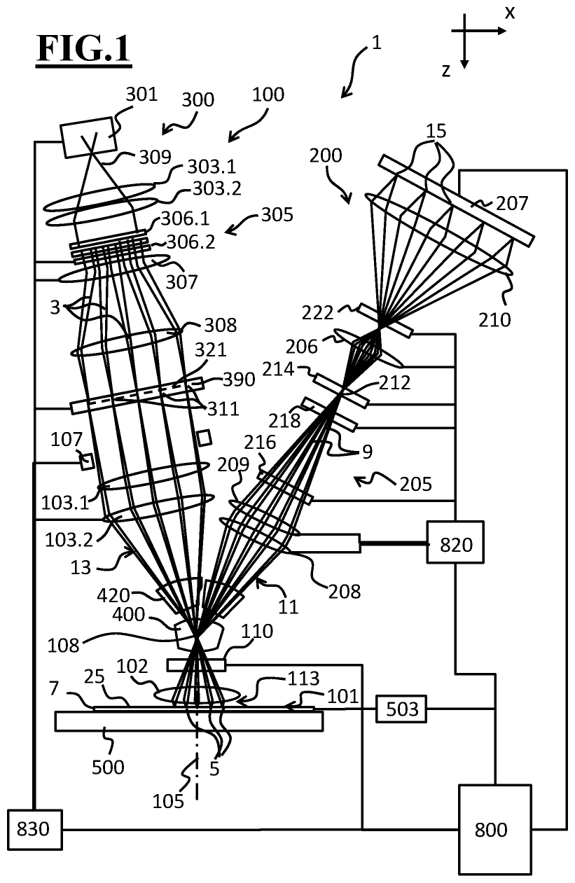

FIG. 1 shows a multi-beam system according to the first embodiment.

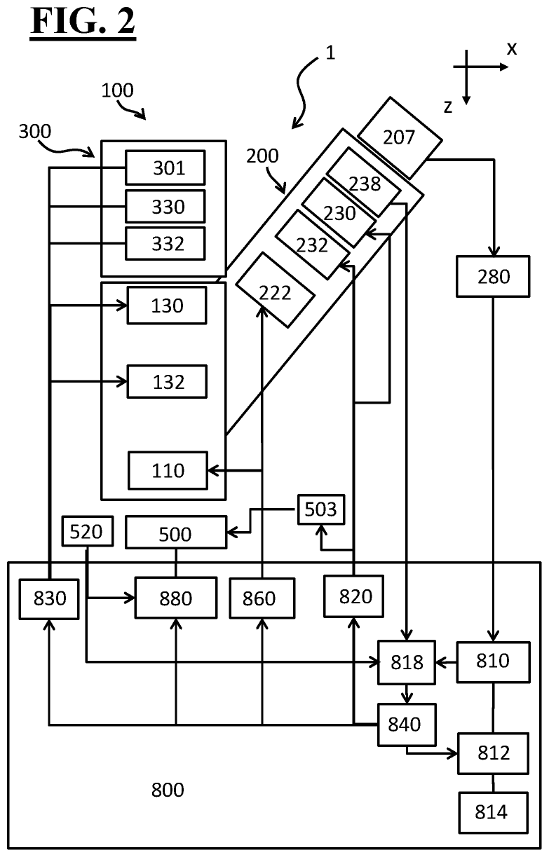

FIG. 2 shows a functional diagram of a multi-beam system according to the first embodiment.

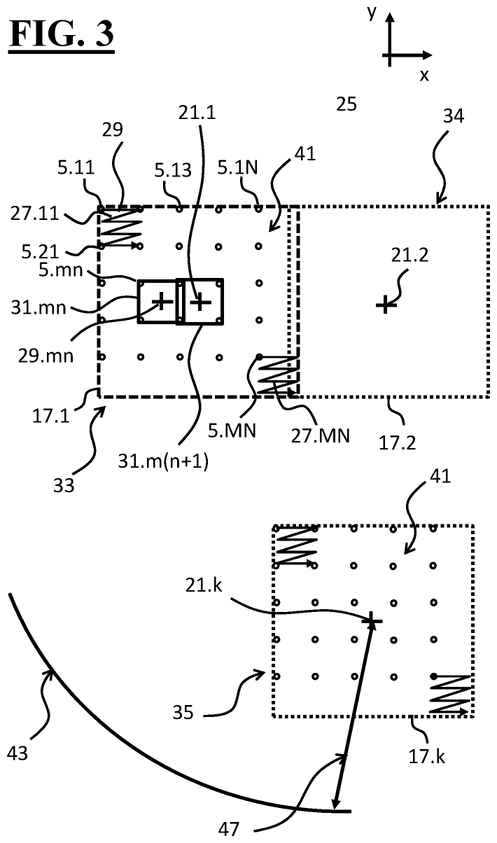

FIG. 3 shows an illustration of an inspection task using a multi-beam system.

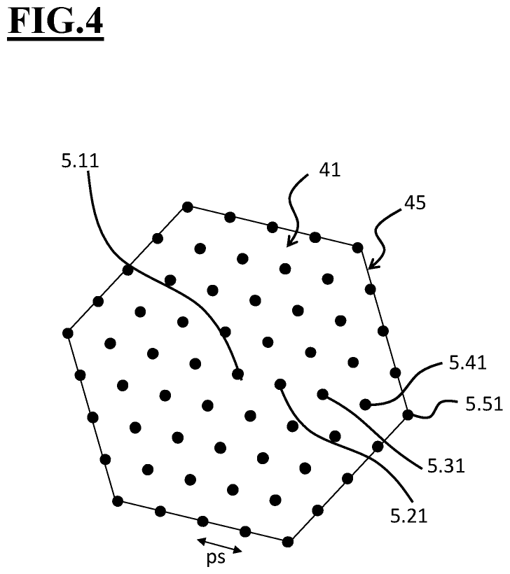

FIG. 4 shows an example of a raster arrangement of the plurality of primary beams or secondary beams of a multi-beam system.

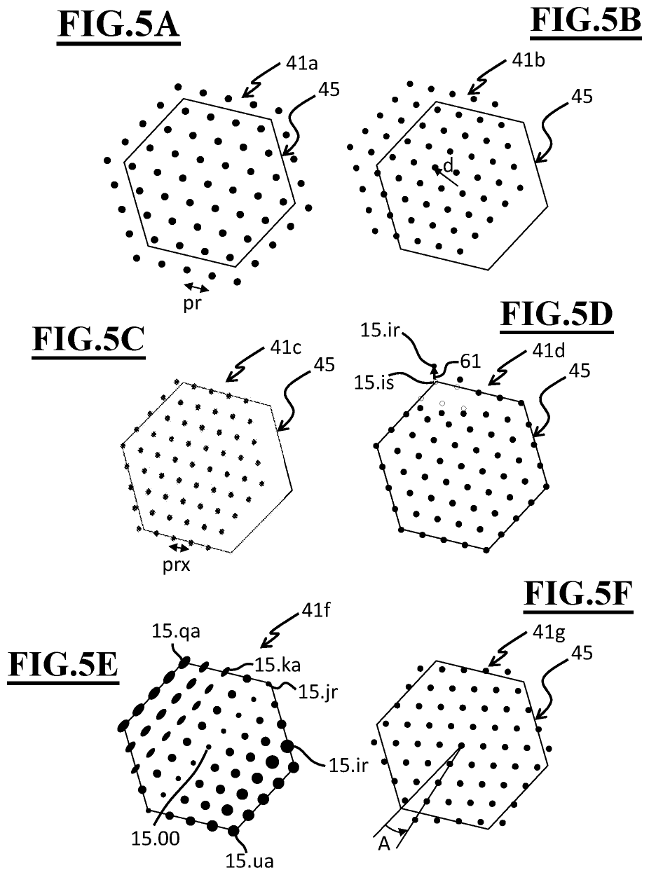

FIG. 5A-5F show an illustration of examples of deviations of a current raster arrangement from a predefined raster arrangement, and of examples of deviations of the beam shape or focal spot size of at least one focal point of a particle beam of the raster arrangement.

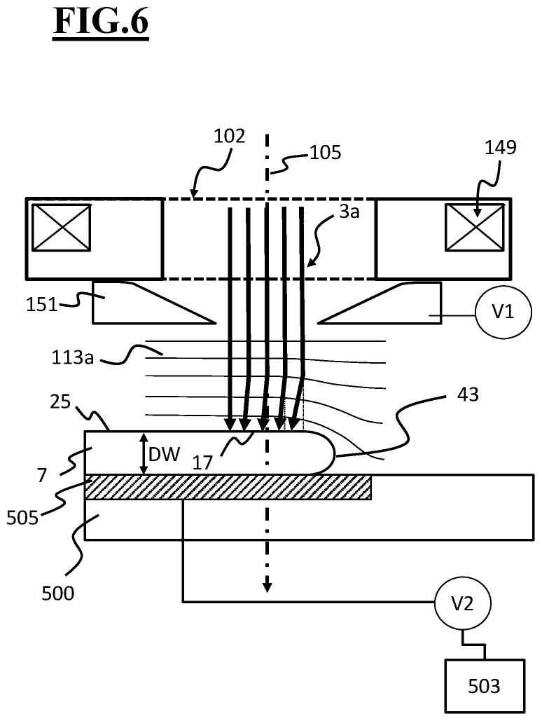

FIG. 6 shows an illustration of an inhomogeneous extraction field at an edge of an object using the example of a wafer edge.

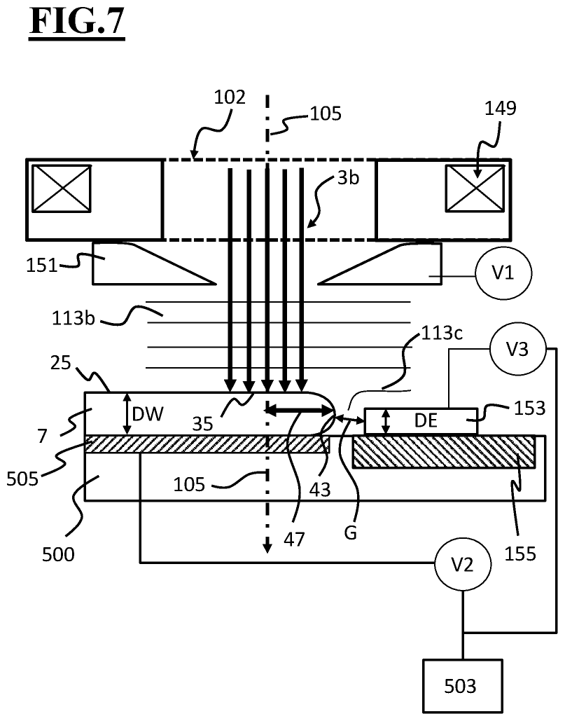

FIG. 7 shows a cross-sectional illustration of a ring-shaped correction electrode according to the second embodiment.

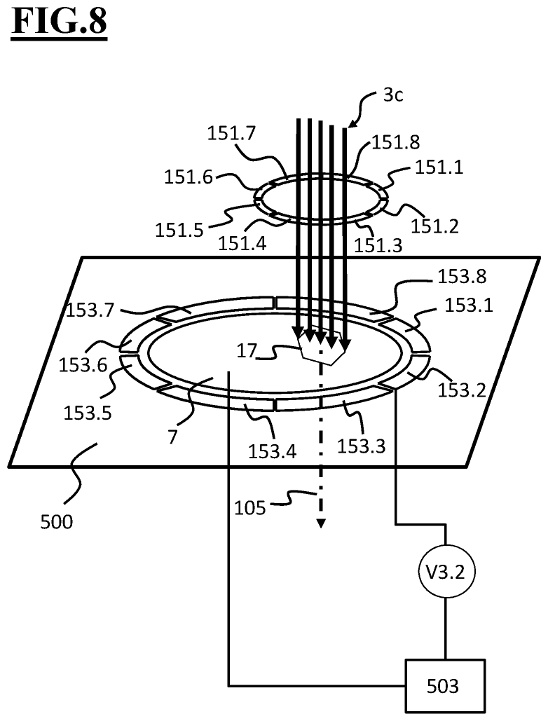

FIG. 8 shows an illustration of a segmented correction electrode and of a segmented counter electrode according to the third embodiment.

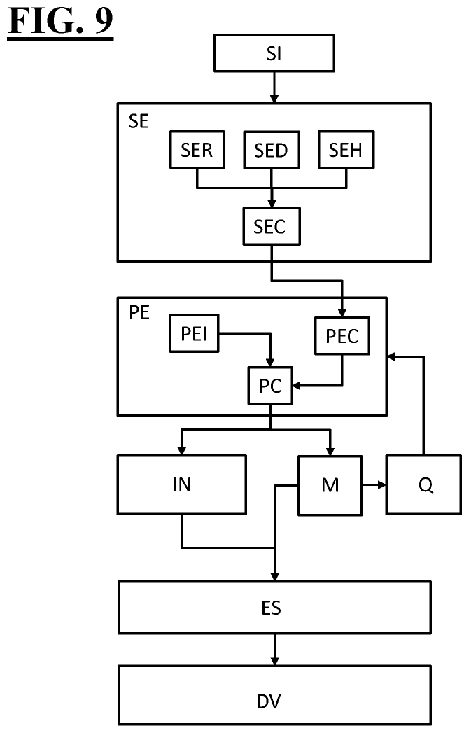

FIG. 9 shows an illustration of the method for operating a multi-beam system with parameter adjustment according to the fourth, fifth or sixth embodiment.

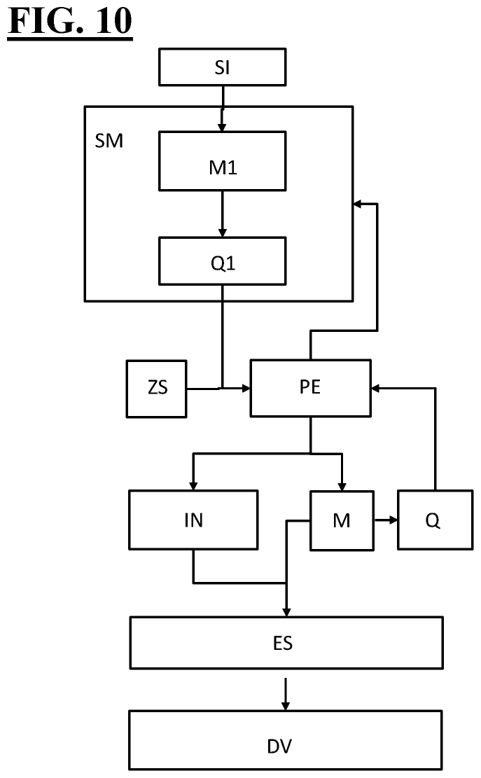

FIG. 10 shows an illustration of the method for operating a multi-beam system with parameter adjustment according to the seventh embodiment.

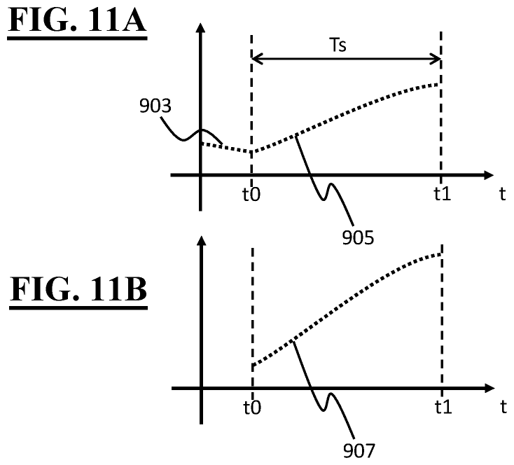

FIGS. 11A-11B show an illustration of a dynamic behaviour using the example of sample charging and a dynamic change in an adjustment parameter of a multi-beam system.

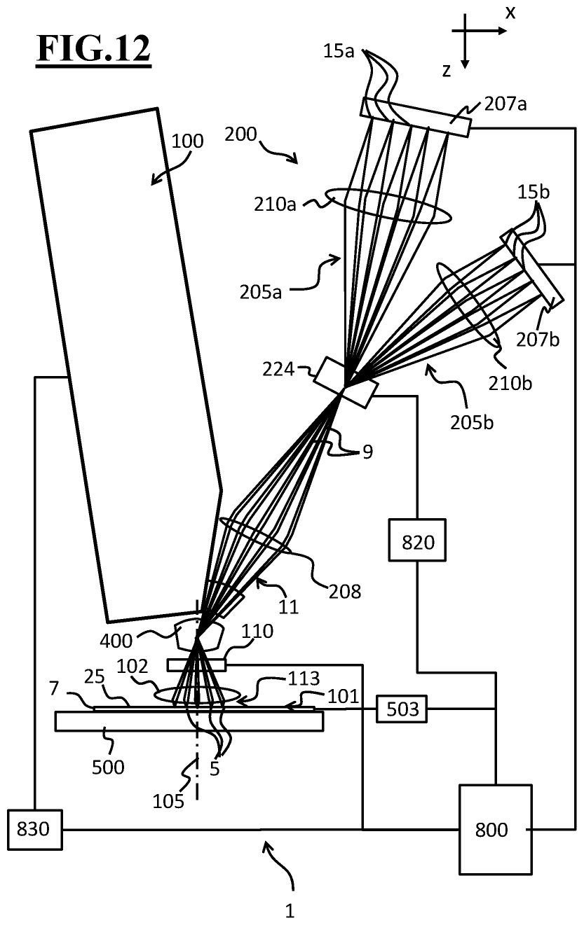

FIG. 12 shows a multi-beam system according to the ninth embodiment.

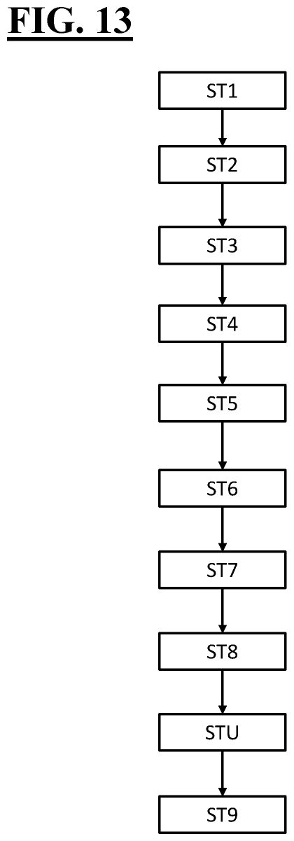

FIG. 13 shows a method for operating a multi-beam system according to the first embodiment.

Below, the same reference signs denote the same features, even if these are not explicitly mentioned in the text.

FIG. 1 is a schematic illustration of a multi-beam system 1, which uses a plurality of particle beams. The particle beam system 1 generates a plurality of J primary particle beams 3 which strike an object 7 to be examined in order to generate there interaction products, e.g. secondary electrons, which emanate from the object 7 and are subsequently detected. The multi-beam system 1 is of the scanning electron microscope (SEM) type, which uses a plurality of primary particle beams 3 which are incident on a surface of the object 7 at a plurality of locations and generate there a plurality of electron beam spots, or spots 5, that are spatially separated from one another. The object 7 to be examined can be of any desired type, e.g., a semiconductor wafer, in particular a semiconductor wafer with HV structures (i.e., with horizontal and/or vertical structures), or a semiconductor mask, and comprise an arrangement of miniaturized elements or the like. The surface 25 of the object 7 is arranged in a first plane 101 (object plane) of an objective lens 102 of an illumination system 100. The optical axis 105 of the objective lens 102 is aligned perpendicular to the surface 25 of the object 7 and aligned parallel to the course of the beam through the objective lens 102.

The plurality of beam focal points 5 of the primary beams form a regular raster arrangement of incidence locations, which are formed in the first plane 101. The number J of incidence locations may be five, twenty-five, or more. In practice, the number of beams J, and hence the number of incidence locations 5, can be chosen to be significantly greater, such as, for example, J=10×10, J=20×30 or J=100×100. Exemplary values of the pitch Pi between the incidence locations are 1 micrometre, 10 micrometres and 40 micrometres or more.

A diameter of the minimal beam spots or focal points 5 shaped in the first plane 101 can be small. Exemplary values of this diameter are below 4 nanometres, for example 3 nm or less. The focusing of the particle beams 3 for shaping the beam spots 5 is carried out by the objective lens system 102. In this case, the objective lens system 102 can comprise a magnetic immersion lens, for example. Further examples of focusing mechanisms are described in the German patent DE 102020125534 B3, filed on 30 Sep. 2020, the entire content of which is herewith incorporated in the disclosure.

The primary particles 3 striking the object 7 generate interaction products, e.g. secondary electrons, back-scattered electrons or primary particles that have experienced a reversal of movement for other reasons, which emanate from the surface of the object 7. The interaction products emanating from the surface 25 of the object 7 are shaped by the objective lens 102 to form secondary particle beams 9. The particle beam system 1 provides a detection beam path 11 for guiding the plurality of secondary particle beams 9 to a detection system 200. The detector system 200 comprises a particle optical unit with at least one projection objective 205 for directing the secondary particle beams 9 towards a spatially resolving particle detector 207. In this case, the imaging with the detection system is strongly magnifying such that both the raster pitch of the primary beams on the wafer surface and the size and shape of focal points of the primary beams are imaged in much magnified fashion. By way of example, a magnification is between 100× and 300× such that one nm on the wafer surface is imaged enlarged to between 100 nm and 300 nm. In the process, an image field of a multi-beam system with for example 100 μm diameter is enlarged to approximately 30 mm. In the case of a sufficient signal strength, a small change in the centroid of a focal point of a particle beam on the detector 207 can be determined with great precision. In the case of multi-beam systems with for example F beams along one direction, a scale error becomes visible additionally magnified by the factor F, in accordance with the larger image field. Consequently, a complex multi-beam effect of the particle beams can be determined with great accuracy, in particular a deviation from a specified raster arrangement, for example at opposing focal points which are situated furthest away from the optical axis 105.

The primary particle beams 3 are generated in a beam generation apparatus 300 comprising at least one particle source 301 (e.g. an electron source), at least one collimation lens 303.1 and 303.2, a multi-aperture arrangement 305 and a field lens 307, or a field lens system made of a plurality of field lenses. The particle source 301 generates at least one diverging particle beam 309, which is collimated or at least substantially collimated by the at least one collimation lens 303, and which illuminates the multi-aperture arrangement 305. The multi-aperture arrangement 305 comprises least one multi-aperture plate 306.1, which has a plurality of J openings formed therein in the raster arrangement. Particles of the illuminating particle beam pass through the J apertures or openings and form the plurality J of primary beams 3. Particles of the illuminating beam which strike the plate 306.1 are absorbed by the latter and do not contribute to the formation of the primary beams 3. The multi-aperture arrangement usually has at least a further multi-aperture plate 306.2, for example a lens array, a stigmator array or an array of deflection elements.

Together with the field lens 307 and a second field lens 308, the multi-aperture arrangement 305 focuses each of the primary beams 3 in such a way that beam focal points 311 are formed in an intermediate image plane 321. Alternatively, the beam foci 311 can be virtual. A diameter of the beam foci 311 can be, for example, 10 nanometres, 100 nanometres and 1 micrometre. A further multi-aperture plate 390, for example in the form of a deflector array, may be arranged in the intermediate image plane 321.

The field lens 103.1 and 103.2 and the objective lens 102 provide a first imaging particle optical unit for imaging the plane 321, in which the beam foci 311 are formed, onto the first plane 101 such that the raster arrangement of incidence locations or focal points 5 arises there. Should a surface 25 of the object 7 be arranged in the first plane 101, the focal points 5 are correspondingly formed on the object surface 25 (see also FIG. 2). The plurality of primary beams form a crossover point 108, in the vicinity of which a fast deflector 110 is arranged, the latter being used to collectively and synchronously deflect the plurality of primary beams 3 such that the plurality of focal points 5 are moved simultaneously over the object surface 25. The deflector 110 is driven by a control unit 800 such that the surface 25 of the object 7 is scanned using the plurality of focal points 5 and a plurality of two-dimensional image data of the surface 25 can be acquired. Additionally, a further quasi-static deflector 107 is arranged, the latter being able to align the plurality of primary beams 3 in a manner centred about the optical axis 105.

The objective lens 102 and the projection lens arrangement 205 of the projection system 200 provide a second imaging particle optical unit for imaging the first plane 101 onto the detection plane. The objective lens 102 is thus a lens or a lens system that is part of both the first and the second particle optical unit, while the field lenses 103, 307 and 308 belong only to the first particle optical unit, or the illumination path 13, and the projection lens 205 belongs only to the second particle optical unit, or the detection path 11.

A beam divider 400 is arranged in the beam path of the first particle optical unit between the field lens 103 and the objective lens system 102. The beam divider 400 is also part of the second optical unit in the beam path between the objective lens system 102 and the projection objective 205. The beam divider 400 additionally has a correction element 420 available for the purposes of compensating aberrations of the beam divider 400, at least in the illumination beam path 13.

The detection system 200 comprises a plurality of further components, for example the electrostatic lens 206 and a plurality of further magnetic lenses 208, 209. Together with the projection lens 210, the lenses serve to focus the secondary beams on the spatially resolving detector and, in the process, compensate the imaging scale and the twist of the plurality of beams as a result of a magnetic lens such that the raster arrangement of the focal points 15 of the plurality of secondary beams 9 on the detector plane 207 remains constant. In this case, the first and second magnetic lenses 208 and 209 are designed reversed to one another and have oppositely directed magnetic fields. A Larmor rotation of the secondary electron beams can be compensated by suitably driving the magnetic lenses 208 and 209. Additionally, a further crossover point 212 of the secondary beams, at which an aperture stop 214 is arranged, is arranged in the projection objective 205. Moreover, the detection system 200 has available a second, collective beam deflector 222 which is located in the vicinity of a crossover point of the secondary beams 9, which is operated synchronously with the first beam deflector 110 and which compensates a beam deflection of the primary beams 3 such that the focal points 15 of the secondary beams 9 remain at constant position on the detection plane 207. The detection system 200 has further correction elements available, for example a multi-aperture plate 216 and a further, third deflection system 218.

Further information relating to such multi-beam particle beam systems and components used therein, such as, for instance, particle sources, multi-aperture plate and lenses, can be obtained from the international patent applications WO 2005/024881, WO 2007/028595, WO 2007/028596, WO 2011/124352 and WO 2007/060017 and the German patent applications having the publication numbers DE 10 2013 016 113 A1 and DE 10 2013 014 976 A1, the disclosure of which in the full scope thereof is incorporated by reference in the present application.

The multiple particle beam system furthermore comprises a computer system or control system 800 configured both for controlling the individual particle optical components of the multiple particle beam system and for evaluating and analysing the signals obtained by the multi-detector 207. In this case, the control or controller system 800 can be constructed from a plurality of individual computers or components. By way of example, the control unit 800 has available a first control module 820 for the detection system 200 and a second control unit 830 for the illumination system 100.

Further, the control unit 800 has available a control module 503 for supplying a voltage to the sample 7, the voltage also being referred to as sample voltage below. During use, a field 113 is generated between the objective 102 and the surface 25 of the object 7, for example of the wafer. During use, field 113 decelerates the primary particles of the primary beams 3 before the sample surface 25 is reached and generates an additional focusing effect on the plurality of primary beams 3. At the same time, this field 113 serves during use to accelerate the secondary particles out of the surface 25 of the object 7. Therefore, the field 113 is also referred to as an extraction field 113 but express reference is made at this point to the fact that the extraction field 113 has two effects: firstly, decelerating and focusing the primary beams 3 and, secondly, aligning and accelerating the secondary electron beams 9. The extraction field 113, or the strength and homogeneity of the extraction field 113, therefore has a great influence on the raster arrangement of the primary particle beams 3, and on the shape and size of the focal points of the primary particle beams 3, and additionally also on the yield of the secondary particles and the shape and direction of the secondary particles 9. In the ideal case, the secondary particles are extracted at right angles, or perpendicular to the object surface 25. Inhomogeneous extraction fields 113 may lead to directional deviations of the secondary beams 9, for example, which together with further aberrations lead to a deviation of the raster arrangement of the secondary beams 9 in the detection path 13 or to a change in the size and shape of the focal points 15 of the secondary beams 9 on the detector 207. Inhomogeneous extraction fields 113 already lead to a deflection of the primary particles at an earlier stage, and hence to a deviation of the raster arrangement of the illumination beams 3 and to a change in shape and size of the focal points 5 of the primary beams 3 on the object surface 25. Consequently, the inhomogeneities of the extraction field 113 superimpose and amplify one another in twofold fashion. Global variations of the extraction field 113 may arise due to global effects, for example a tilt or a z-offset of the object 7, or uniform charging of the object 7. Local variations in the electric extraction field 113 may arise due to local effects, for example an object edge or edge of the wafer, general height differences of the object 7 caused by an object topography, or local charging. Variations in the electric extraction field 113 may be static or time varying. By way of example, static variations arise from an unchanging topography or edge of an object 7. Time-varying variations arise from time-varying charging effects. In particular, the raster arrangement reacts very sensitively to variations in the electric extraction field 113 at the object 7 or between the object surface 25 and an electrode within the objective 102 of the multi-beam microscope 1.

FIG. 2 schematically shows further functional aspects of the multi-beam system 1 according to the first embodiment of the disclosure in a section. The illumination system 100 comprises the multi-beam generation device 300 with the particle source 301, slow compensators 330 of the multi-beam generation device 300 and fast compensators 332 of the multi-beam generation device 300. By way of example, the magnetic condenser lenses 303.1 and 303.2 which allow a beam intensity at the entrance to the multi-aperture plate 305 to be altered are slow compensators 330. By way of example, a deflector array 306.2 which can quickly deflect the plurality of primary beams are fast compensators 332. The illumination system 100 further comprises slow compensators 130, for example the magnetic lenses 103.1 and 103.2 or a further, quasi-static beam deflector 107. Slow compensators 130 are further formed by the magnetic lens of the objective lens system 102, the beam divider 400 and the correction element 420 of the beam divider. The illumination system 1 further comprises fast compensators 132, for example the deflector array 390 or a fast, electrostatic focusing lens in the objective lens system 102. The objective lens 102 can additionally comprise further quickly driveable electrode segments, according to the third embodiment of the disclosure, for setting a homogeneous extraction field. The driveable components (301, 330, 332, 130, 132) of the illumination system 100 are connected to the control unit of the illumination device 830 and are driven by the latter during operation. Further, the illumination system 100 comprises the first, fast beam deflector 110 for fast, collective beam deflection of the primary beams 3. The beam deflector 110 is driven by the scanning module 860.

In addition to the spatially resolving detector 207, the detection system 200 of the multi-beam system 1 further comprises slow compensators 230 of the detection system 200 and fast compensators 232 of the detection system 200. By way of example, the magnetic lenses 208 and 209 and the magnetic lens 210 are slow compensators 230. By way of example, the beam deflector 214 or the electrostatic lens 206 are fast compensators 232. Further, the detection system 200 comprises the second, fast beam deflector 222 for fast, collective beam deflection of the secondary beams 9. The second beam deflector 222 is driven synchronously with the first beam deflector 110 by the scanning module 860. The secondary beams 9 pass through both the first beam deflector 110 and the second beam deflector 222. The second beam deflector 222 is designed to carry out the so-called anti-scan, which compensates the otherwise arising scanning movement of the secondary beams 9 upon incidence on the detection unit 207. The detection system 200 further has available further sensors 238 which are arranged in the periphery of an aperture stop 214, for example.

The semiconductor wafer 7 is positioned by a displacement stage 500 below the objective lens 102. The displacement stage 500 can be a 6-axis displacement stage which can position the surface 25 of the sample 7 in the object plane or first plane 101 in 6 degrees of freedom. In this case, the position accuracy in the z-direction is under 50 nm, for example better than 30 nm. The position of the displacement stage 500 is monitored and controlled by sensors 520 of the control unit 880 in this case. The sample voltage for a homogeneous extraction field is controlled by way of the control module 820 of the detection unit 820, together with the slow and fast compensators 230, 232 of the detection module 200. It is additionally possible to drive at least one further correction electrode, which is arranged in the periphery of the wafer 7 in accordance with the second exemplary embodiment.

The detection unit 207 may comprise at least one scintillator for converting the secondary electrons into light, and a plurality of light-optical detectors. Such detectors can be CMOS or CCD sensors or else be formed by a plurality of photodiodes, for example avalanche photodiodes. The sensors may be arranged directly behind the scintillator or an optical imaging system or light guides may be arranged between the scintillator and the sensors. It is also possible to use sensors that detect electrons directly and convert these into electrical signals. A special form of the detection unit is described in the German patent with the number DE 102018124044 B3, the disclosure of which is incorporated into the present application in full by reference. Therein, the detection unit 207 consists of a scintillator on which the plurality of focal points 15 of the secondary particle beams are formed. The light generated is imaged onto a fibre bundle by way of an imaging system, with each fibre being coupled to a photodiode. The imaging system further contains a beam divider which steers some of the generated light onto a CMOS sensor. Using this sensor, it is possible to monitor the raster arrangement and the shape and size of the individual focal points 15. Instead of output coupling some of the light using the beam divider, it is alternatively also possible to capture and evaluate the light emitted by the scintillator in the backward direction, that is to say the light emitted in the direction of the incident particle beams, by way of a CMOS camera.

The detection unit 207 is connected to an image data converter 280 which converts the temporal sequence of analogue electrical signals, for example voltages of the sensors, into a temporal sequence of digital signals. By way of example, the image data converter 280 of the plurality of J secondary beams has a parallel computer architecture available. In this case, the image data converter 280 contains a plurality of analogue-to-digital converters connected in parallel, which can be designed as ASICs connected in parallel, for example. The scanning frequency FS of the two deflection systems 110 and 222 approximately corresponds to the inverse of the dwell time of a primary beam 3 on a focal point 5 on the sample surface 25. This dwell time is typically 50 ns. However, dwell times of 10 ns, 20 ns or 100 ns are also possible. While an image is recorded, the read-out frequency or the frequency FC of the data conversion using the image data converter 280 corresponds to the scanning frequency FS, and so digital image data for a plurality of image pixels are acquired for a plurality of focal points with FS=FC. Usual clock rates of the deflection systems and the analogue-to-digital conversion using the image data converter 280 are between FS=FC=10 MHz to 100 MHz in this case, but higher clock rates of more than 100 MHz are also possible.

The control unit 800 has available a control module 830 for controlling the illumination device 100, a control module 880 for controlling the displacement stage 500, and a control module 820 for controlling the detection unit 200. A data acquisition device 810 is connected firstly to the image data converter 280 and secondly to an image data memory 814. Additionally, a digital image processing unit 812 is arranged between image data memory 814 and data acquisition device 810. A sensor data module 818 receives time-averaged data of the raster arrangement of the secondary beams 9 and other sensor signals, for example from the further sensors 238 of the detection module 200 or from the control module of the displacement stage 500 with the position sensors 520. The control unit 800 further has available a control processor 840, which evaluates the sensor data of the sensor data module 818 and determines corresponding control signals, for example parameters for setting components of the illumination system 100 and of the detection system 200.

In a multi-beam particle beam system 1 as per FIG. 2, the sample 7 is at a potential for generating the aforementioned extraction field 113 which firstly decelerates the primary particles and secondly accelerates the secondary particles out of the sample. To set the sample potential, the receiving stage for the sample or the wafer 7 is connected to the voltage supply 503 for the object voltage.

A method of wafer inspection is described with reference to FIG. 3. FIG. 3 shows the surface 25 of a wafer 7 with a sequence of a first inspection position 33, a second inspection position 34 and a third inspection position 35. The third inspection position is at a distance 47 from the wafer edge 43. With its upper side 25, the wafer is arranged in the first plane or object plane 101 of the multi-beam system 1. In this case, the wafer is arranged in an optimal focal plane of the plurality of the primary beams 3. In this example, the plurality of the J primary beams 3 have a rectangular raster arrangement 41. The centre 21.1 of the first image field 17.1 scanned by the plurality of primary beams 3 is aligned approximately with the axis of symmetry 105 of the objective lens 102. The image fields 17.1 to 17.k correspond to different inspection positions of the sequence of wafer inspection tasks. By way of example, the predefined first inspection position 33 and the second inspection position 34 are read from a control file. In this example, the first inspection site 33 is adjacent to the second inspection position with the image fields 17.1 and 17.2 with a first centre position 21.1 and a second centre position 21.2. Then, the first centre position 21.1 of the first inspection position 33 is initially aligned under the axis 105 of the objective lens 102. In this case, methods for detecting a coordinate system of a wafer and aligning a wafer are known from the prior art.

The plurality J of primary beams 3 are then deflected together by the scan deflector 110 over in each case small sub-fields 31.11 to 31.MN and, in the process, each beam scans a different sub-field, for example sub-field 31.mm or sub-field 31.m(n+1). Exemplary scanning patterns or scanning paths 27.11 and 27.MN are schematically illustrated in the first sub-field 31.11 and in the last sub-field 31.MN. Further, in exemplary fashion, the focal points 5.11, . . . , 5.MN of the respective different primary beams are illustrated in each case at the upper left corner of an assigned sub-field. Further, sub-fields 31 each have a centre; the centre 29.mn of the sub-field 31.mn is labelled by a cross in exemplary fashion. Here, a plurality of sub-fields 31.11, . . . , 31.MN are in each case scanned in parallel by the plurality of the J primary beams with focal points 5.11 to 5.MN and a digital image data record is acquired for each of the J sub-fields 31.11 to 31.MN, each image data record being able to comprise 8000×8000 pixels, for example. In this case, the pixel size can be defined and be 2 nm×2 nm, for example. However, a different number of pixels between 4000×4000 and more than 10 000×10 000 pixels are also possible, and other pixel sizes of for example 3 nm, 1 nm or less can be set. Once the digital image data of the first image field 17.1 have been acquired, the image data of the individual sub-fields 31.1 to 31.MN of the first image field 17.1 are combined to form an image data record. Subsequently, the second inspection position 34 is positioned under the axis of the objective 102 and the digital image data of the second image field 17.2 are acquired. The procedure is continued, for example with the second inspection position 35 with the image field 17.k. Naturally, the raster arrangement 41 of the primary beams 3 is not restricted to rectangular raster arrangements, other raster arrangements include, for example, hexagonal rasters or an arrangement of the primary beams on concentric rings or one ring. In this case, the lateral resolution of the digital image data is determined substantially by the diameter of the focal points 5 of the primary beams 3 on the object surface 25. FIG. 4 shows a typical raster arrangement 41 with an arrangement of the plurality of J=91 primary beams 3 with a hexagonal raster with a pitch ps of for example 10 μm on the surface 25. Some beams along one direction are denoted by 5.11, 5.21, 5.31, 5.41 and 5.51. For illustrative purposes, the outer focal points in the periphery are additionally connected by a line 45 which illustrates the edge of the ideal raster arrangement.

During an inspection task, the raster arrangement 41 is displaced synchronously over an object surface 25, and image data of a surface 25 of a wafer 7 are acquired. The anti-scan using the deflection device 222 ensures that the raster arrangement 41 of the secondary beams 9 remains fixed in position or stationary on the detector 207. However, there may be changes of the raster arrangement 41 in the detection plane of the detector 207 before or during the inspection task, the changes significantly impairing the position and reproduction fidelity of the semiconductor structures on the object surface 25. In this case, disruptive changes of the raster arrangement 41 arise in the primary beam 11 and bring about a change in the raster arrangement 41 of the focal points 5 of the primary beams 3. The changes of the raster arrangement 41 of the primary beams bring about corresponding changes of the raster arrangement 41 of the secondary beams 9, the latter of course arising at the focal points 5 of the primary beams 3 on the object surface 25. The changes of the raster arrangement 41 of the secondary beams 9 may still be amplified in the secondary path and ultimately lead to, for example, the changed raster arrangements 41a to 41g of the focal points 15 of the secondary beams 9 in the plane of the detector 207. The changed raster arrangements of the focal points 15 of the secondary beams 9, together with the changed shapes and sizes of the focal points 15, are also referred to as complex multi-beam effect.

To acquire the raster arrangement 41 of the plurality of J secondary beams 9, the multi-beam system 1 according to the disclosure can be configured to carry out various methods. In a first method there is time-averaging of the signals by the image data converter 280 by temporal integration of the image signals. To this end, the image data converter 280 is operated at a significantly lower data conversion frequency FC<FS in relation to the scanning frequency FS, and so averaging of the image data is implemented over a plurality of focal points on the object surface 25. By way of example, the data conversion frequency FC can be 1/10 of the scanning frequency, FC<FS/10, or even less, for example FC<FS/100 or FC<FS/1000 or even significantly less. In one example, the image data acquisition is implemented with two detectors in parallel, and a first detector is operated for high-resolution imaging using a first image data converter at a first data conversion frequency FC1=FS, which equals the scanning frequency; a second detector is operated using a second image data converter at an image evaluation frequency, and so only a few images or only one image of the raster arrangement is determined during high-resolution imaging of an image portion at an inspection position using the first detector. In an example, the high-resolution image comprises 8000×8000 pixels; with a dwell time of 50 ns or a scanning frequency of FS=20 MHz, this then yields an image recording time T2 of approximately 3.2 s. By way of example, the second detector camera can be a CMOS sensor which for example has a frame rate of 10 to 100 frames per second with an image recording time T1 of 0.1 s to 10 ms, or an image frequency of 1 Hz to approximately 0.1 kHz. Consequently, approximately 30 to 300 inspection images of the raster arrangement can be generated while recording the high-resolution image.

As an alternative to reducing the data conversion frequency FC, it is also possible to increase the scanning frequency. By way of example, a scanning frequency for measuring the raster arrangement 41 can be increased by a factor of 10, from 50 MHz to 500 MHz. By way of example, the scanning frequency FS can be increased to FS=10× FC or FS>100×FC. In the first method there is time averaging of the signals by the sensor data module 818, which evaluates mean values for each secondary beam from spatially resolved digital image data and which detects a change in the raster arrangement. In the second method, the time averaging of the signals is implemented by fast scanning using the scanning deflector 110 and 222.

FIG. 5 shows a few examples of changes in the raster arrangements 41 in relation to an ideal raster arrangement 45. FIG. 5 illustrates the deviations of the raster arrangement and the shapes and sizes of the focal points 15 of the secondary beams on the detector 207. FIG. 5A shows a change in the pitch of the beams with a spacing or pitch of pr>ps. As explained above, the ideal pitch is ps=10 μm, for example. A change in the imaging scale leads to a change in the spacing or pitch by for example 0.1% or even less, for example by 2 nm. The scale error accumulates by the change in the pitch multiplied by the number of beams between maximally spaced apart beam focal points in the raster arrangement 41a, to 18 nm in the example of FIG. 5A with a maximum of nine beams across a diagonal. By way of the enlargement of the imaging of the raster arrangement on the object surface 25 onto the detector 207 with a magnification of 100× to 300×, the error accumulates to 2 μm to 5 μm. FIG. 5A depicts an enlargement of the raster arrangement 41a with an increased pitch pr, but the pitch pr can also be reduced. A very large magnification change is shown for purposes of illustration.

By way of the magnification of the detection path, the complex multi-beam effect is imaged in enlarged fashion on the detection camera. Additionally, the cause for the complex multi-beam effect (charging, edge, tilt on the wafer, etc.) also affects the secondary electrons. By way of example, the lower energy secondary electrons react more sensitively in this case than the higher energy primary electrons to variations in the extraction field, and for example a further distortion is added in addition to the deviations of the primary beam on account of sample influences.

FIG. 5B shows a raster arrangement 41b that has been laterally offset by an offset vector d. An offset or displacement, or a migration of the raster arrangement, brings about an offset in the digital image data and may for example lead to aberrations when stitching a plurality of image portions. FIG. 5C shows a compressed raster arrangement 41c. A compression of the raster arrangement corresponds to a change in spacing or pitch in only one direction, for example the x-direction, as indicated here by the modified pitch prx. Additionally, local effects may occur and may lead to only a local beam deflection of individual beams in a raster arrangement 41d. In FIG. 5D, this is illustrated using the example of 5 beams, specifically using an example with a target position of a beam 15.is and a real position 15.ir and a local displacement 61 of the spot position. FIG. 5E illustrates the effect of a deviating beam shape of at least one beam in a raster arrangement 41f. A beam 15.jr has an ideal beam shape, from which for example a beam 15.ir deviates in terms of size and a further beam 15.ka deviates in terms of shape. FIG. 5E shows a simplified example of a systematic deviation of the shape or size of the focal points over the raster arrangement. In this example, a profile can be deduced from at least three shapes or sizes of at least three focal points, and hence it is possible to distinguish between a local effect and a global effect such as a tilt. The example elucidates an effect of a diagonal tilt of a focal plane or best setting plane 101 in relation to the wafer surface 25, with the focal point 15.ua being located closer to the objective lens than the focal point 15.qa. By detecting the shape and size of the for example focal points 15.qa and 15.ua and the central focal point 15.00, it is possible to distinguish a systematic tilt from other causes for the deviations of the shape and size of the beam focal points. In principle, however, it is also possible to determine shape deviations and size deviations of all focal points.

FIG. 5F finally shows a twisted raster arrangement which is twisted at an angle A in relation to an ideal raster arrangement 45.

Other deviations of the raster arrangement are also possible, for example a keystone distortion. Further, the deviations usually occur as a combination or superposition of individual deviations.

The multi-beam system 1 is set with predefined parameters for an inspection task. The control processor 840 is configured to determine the various predefined parameters for an inspection task during operation, and to use this to drive the components of the multi-beam system 1. Components driven by parameters include for example the slow and fast compensators 130, 132 of the illumination system 100, slow and fast compensators 330, 332 of the multi-beam generation device 300, the slow and fast compensators 230, 232 of the detection system 200, or the displacement stage 500. By way of example, the spacing or pitch ps of the individual beam focal points 5 on the surface 25 of the wafer 7 are set by way of these parameters and the focal points are set in an optimal focal plane in the plane 101. Further changeable parameters include the beam intensity, which may be set using the condenser lenses 303 for example. The noise performance can be set by way of the beam intensity and the dwell time. The parameter that determines the strength of the extraction field further influences the resolution and the kinetic energy of the secondary electrons. A certain twist of the raster arrangement on the object surface sets in by way of the focusing effect of the magnetic lens of the objective lens system 102. The scanning program is set using further parameters. Further components of the detection system are driven by parameters such that the plurality of focal points 15 of the secondary beams 9 are incident on the detector 207 at predefined positions and are kept constant there such that the image data can be acquired in a time-sequential sequence. In summary, a set of parameters is also referred to as working point. The control processor 840 of a multi-beam system 1 according to the first embodiment is designed to operate the multi-beam system 1 at a plurality of different, predefined working points.

By way of example, the sensor data module 818 (see FIG. 2) is designed to average over the object contrast by way of time averaging of the image data during operation and to measure the focal positions 15 of the current raster arrangement 41 of the secondary beams 9. Additionally, at least one shape and size of a focal point 15 can be determined, for example of the focal point 15.ir or the focal point 15.ka. The sensor data module 818 is configured to transmit the current raster arrangement 41 and the shape and size of the at least one focal point 15 to the control processor 840. The control processor 840 is configured to determine the deviation of the current raster arrangement 41 from the ideal raster arrangement 45 at the pre-set working point therefrom, and a shape deviation and size deviation of the at least one focal point 15. The control processor 840 is configured to deduce disruptive influences from the deviations and to determine corresponding parameter changes which are suitable for reducing the disruptive influences. The deviations of the raster arrangement 41, and of the shape and size of the at least one focal point 15 of a secondary beam 9, corresponding to the disruptive influences can be determined in advance. It is likewise possible to determine changes of the parameters of the working point, which are suitable for reducing the disruptive influences, in advance and to store these. To this end, the control processor 840 comprises a storage module in which the parameter changes which are suitable for reducing certain disruptive influences are also stored in addition to the parameters for various working points.

A few disruptive influences or causes for changes in the raster arrangement and a change in the shape and size of a focal point are listed below.

A mechanical defocus, for example as a result of a deviating thickness of a wafer, brings about a change in the magnification or the pitch of the focal points in the raster arrangement and brings about increased spot diameters in accordance with the raster arrangement 41a. Additionally, there can be a changed size of a focal point, as illustrated for example on the basis of the focal point 5.ir in FIG. 5E. The mechanical defocus can be compensated by a z-movement of the stage or displacement stage 500. Alternatively or in addition, the strength of the extraction field 113 can be changed and further electrostatic components within the illumination path and the detection path can be set to focus on the defocussed object surface. The extraction field will be discussed below. A further option for compensating a mechanical defocus is provided by changing the excitation of magnetic lenses, for example the objective lens 102.

A local inclination of the sample surface, for example when a wafer bends, leads to a homogeneous gradient of the extraction field and to an offset of the raster arrangement according to the raster arrangements 41b. Additionally, a typical astigmatism, for example a constant astigmatism, may occur over the plurality of beams and may lead to a constant elliptical beam shape, like the beam shape of beam 5.ka in FIG. 5E. It is possible to tilt the wafer 7 as a correction measure. Alternatively, it is possible to generate a targeted, homogenous field gradient in the extraction field 113 which counteracts the effect of the inclination of the object surface 25 or the field gradient of the extraction field 113. The extraction field will be discussed below. An offset of the raster arrangement 41b of the primary beams 3 on the wafer surface 25 can be compensated by a deflector 107 in the primary path. Alternatively or in addition, appropriate corrections of the astigmatism, for example, can be carried out using the available fast and slow correction elements 130, 132 and the deflection systems 110, 222.

Effects of an inhomogeneous extraction field 113 at the edge of a wafer lead to a migration or an offset of the raster arrangement 41b in combination with a constant astigmatism. A mechanism for correcting an edge effect is discussed below. A complex multi-beam effect at the edge of the wafer 7 and an effect resulting from tilting may be very similar. The compensation measures may be similar. However, aberrations that vary more significantly over the image field arise at the edge of a wafer, for example there is no constant offset and no uniform astigmatism over the image field but a slight distortion in the positions of the focal points or a more complex field dependency of the astigmatism.

Homogeneous charging of the sample surface 25 likewise causes a magnification change and enlarged spot diameters. At the same time, there is a lateral displacement of the raster arrangement 41b corresponding to FIG. 5B. In this case, the extraction field 113 can, for example, be dynamically increased in synchronized fashion with the charging in order to counteract the charging. To this end, the sample potential is dynamically and synchronously adapted by way of the voltage V2, for example, in order to keep the electric extraction field constant and counteract the sample charging. Potentials V1 and V3 that depend on the sample potential or the voltage V2 are likewise adapted in order to keep an extraction field constant (see FIGS. 6 to 8 and the discussion below). Additionally, further electrostatic components within the illumination path 13 and the detection path 11 can be set for focusing on the charged object surface 25. An offset of the raster arrangement 41b of the primary beams can be compensated by a beam deflector 107 in the illumination system. Charging of the object surface 25 may also lead to a change in the kinetic energy of the extracted secondary electrons 9 and hence lead to a changed rotation of the raster arrangement of the secondary beams 9, as shown in FIG. 5F. A rotation of the raster arrangement 41 of the secondary electron beams 9 can be compensated by driving a magnetic lens pair differently.

Local charging of a portion of the sample surface at the inspection position (33, 35) according to the image field 17 of the raster arrangement 41 of the primary beams 3 likewise leads to a change in magnification in conjunction with a lateral offset. However, there additionally is a change in the shape of the focal points 5 of the edge beams of the raster arrangement 41. Edge beams are those beams that no longer have an adjacent beam in one direction. The shape changing and size changing effect of the focal points 5 is particularly pronounced in the corners of the raster arrangement 41.

Inspection positions such as the inspection positions 33 and 35 are influenced by latent charging of preceding or adjacent inspection positions or adjacent image fields. This may occur, in particular, if like in the example of FIG. 3 an inspection position 33 is stitched together from two image fields 17.1 and 17.2. This leads to an inhomogeneous gradient of the extraction field 113 and to an offset of the raster arrangement, corresponding to the raster arrangements 41b. Additionally, there is a distortion of the raster arrangement corresponding to the raster arrangements 41c. Further, a linearly increasing profile of an astigmatism may occur over the plurality of beams and may lead to an elliptical beam shape, like the beam shape of beam 5.ka in FIG. 5E. By way of example, these effects can be influenced by changing the sequence of the inspection positions.

Local charging only distorts individual spot positions or spot shapes, as illustrated in FIG. 5D. Local charging effects can be influenced by optimizing the working point or a change in the scanning strategy. In this case, adjusting the working point can comprise adjusting the landing energy or beam current. In this case, changing the scanning strategy may comprise fast scanning in conjunction with averaging over many frames generated with a short dwell time (this is known as “frame averaging”). In this case, the beam current can still be reduced and the number of images over which averaging takes place can be increased. Further scanning strategies consist in a decomposition of a sub-field 31 into smaller sub-fields which are individually scanned in succession and subsequently stitched together. Further options include the targeted introduction of discharging processes during the image generation; such discharging processes may be caused by pauses during the imaging or by stimulated discharge, for example by operating the multi-beam system in what is known as the mirror mode. In a further example, an inspection position to be measured may be pre-charged by a preceding irradiation. By way of example, a scanning procedure at the inspection position may be carried out at a lower speed and with a smaller irradiation dose in order to reduce or compensate local charging effects. A further mechanism is an adjustment of the sub-field size by way of the deflection scanner 110 and digital correction of the lateral position of individual digital images of individual sub-fields in accordance with the beam offset 61 of an individual primary beam, for example like the primary beam 15.ir in FIG. 5D.

The control processor 840 is configured to store the predetermined relationship of disruptive influences or causes for a complex multi-beam aberration. A complex multi-beam aberration is understood to mean a change in the raster arrangement 41 and a change in the shape and size of at least one focal point, for example of three focal points or all focal points. Further, the control processor 840 is configured to store predefined parameters for correcting or compensating the disruptive influences. The control processor is further configured to deduce disruptive influences or a cause from a currently determined complex multi-beam aberration. In this case, the control processor resorts to the stored relationship of disruptive influences or causes and the suitably altered parameters for correcting or compensating the disruptive influences or causes, and drives the multi-beam system 1 using the altered parameters.

Hence, the first embodiment of the multi-beam system comprises an improved method for operating the multi-beam system 1 for inspecting objects 7, such as a semiconductor wafer. The method is illustrated in FIG. 13 and includes the following steps:
Step 1: Arranging a substantially planar object 7 on a reception area 505 of a displacement stage 500 and arranging an object surface 25 of the object 7 in an object plane 101 using the displacement stage 500.
Step 2: Illuminating the object surface 25 using a plurality of J focal points 5 which are generated by a plurality of J primary beams 3 in a predefined raster arrangement 41.
Step 3: Scanning the object surface 25 with the plurality of J focal points 5 by synchronously deflecting the plurality of J primary beams 3 in the predefined raster arrangement 41 over a first plurality of scan positions.
Step 4: Collecting a plurality of secondary particles generated from the plurality of focal points 5 from the object surface 25 at the plurality of focal points 5 of the primary beams 3, and focusing the plurality of secondary particles on a spatially resolving detector 207.
Step 5: Detecting signals of the secondary particles and generating an image of the plurality of focal points 15 of the secondary particles using the spatially resolving detector 207. In an example, the detection of the signals contains time-averaging of the signals of the secondary particles over a second plurality of scan positions.
Step 6: Determining a complex multi-beam effect consisting of a change in the raster arrangement 41 of the plurality of focal points 15 of the secondary particles relative to the predefined raster arrangement 45 from the image of the plurality of focal points 15 of the secondary particles. In an example, determining the change in the raster arrangement 41 additionally comprises the determination of a beam shape deviation of at least one focal point 15 of the plurality of focal points 15 of the secondary particles, the beam shape deviation comprising an ellipticity or a diameter deviation.

In this case, the deviation of the raster arrangement 41 comprises at least one of the following errors: a scale error 41a, an offset error 41b, a distortion 41c, a twist 41g, or a local deviation 41d of only individual beams of the raster arrangement 41.

The change in the shape and size of the focal points 15 comprises at least one of the following aberrations: a constant astigmatism, a linear astigmatism with a linear dependency of the astigmatism over the position in the raster arrangement 41, a constant focal aberration, a linear focal aberration with a linear dependency of the focal aberration over the position in the raster arrangement 41.
Step 7: Determining at least one cause of the change of the raster arrangement 41, wherein the change in the raster arrangement 41 contains an offset error, an isotropic scale difference, a distortion or magnification difference between two non-parallel directions, a rotation or a keystone distortion.

In a further step, a decomposition of the change of the raster arrangement 41 can be implemented according to global changes and local changes of the raster arrangement.
Step 8: Determining optimized parameters for driving components of the multi-beam system for compensating the changes of the raster arrangement and driving the multi-beam system with the optimized parameters.

In this case, the determination is implemented for example via a stored table of parameter changes which are suitable for compensating individual, normalized effects of the complex multi-beam effect. Then, the optimized parameters are calculated for example by multiplying the amplitude of a change in the raster arrangement by the associated stored parameter changes. Specific examples of the first embodiment comprise a determination of a local inclination error of the planar object surface 25 from the combination of an offset error of the raster arrangement 41 and a beam shape deviation in the form of an ellipticity. In a further example, the first embodiment comprises determining a spacing error of the planar object surface 25 from the combination of a scale difference of the raster arrangement 41 and a beam shape deviation in the form of a diameter deviation of the at least one focal point. In a further example, the first embodiment comprises determining a global charging effect of the planar object surface from the combination of a scale error of the raster arrangement 41 and an offset of the raster arrangement 41 in the case of a virtually unchanging beam diameter. In a further example, the first embodiment comprises determining a distance from a topographic structure, for example the edge of the object 43, from an offset of the raster arrangement 41 and a distortion in the direction of the offset or a magnification difference between two non-parallel directions. In a further example, the first embodiment comprises determining a local charging effect from an irregular change in the raster arrangement, consisting of at least two different position deviations of at least two focal points from the predefined raster arrangement. In a further example, the first embodiment comprises determining a local charging effect from an irregular change in the raster arrangement, consisting of at least two deviations of at least two focal points comprising at least one beam shaping deviation and at least one position deviation from the predefined raster arrangement.
Step 9: Setting the optimized parameters of the multi-beam microscope in the illumination system and of the extraction field and, if desired, of the detection system as well, and capturing a high-resolution image of the object surface.

The optimized setting parameters contain parameters of components within the illumination path 13 and within the detection path 11 of the multi-beam system 1, and may also contain a realignment of the wafer 7 with the displacement stage 500 at the first inspection position (33, 35). Further, the extraction field 113 is arranged in the illumination path and detection path, and setting the optimized parameters of the multi-beam microscope contains driving correction electrodes for influencing an extraction field 113 at the inspection position (33, 35) on the surface 15 of the wafer 7. Compensators comprise a deflection apparatus 107 for compensating an offset of the raster arrangement 41 on the surface 25 of the wafer 7, and a change in the working point of the multi-beam system 1, for example for setting a scale of the raster arrangement 41, a change in the scanning program for the beam deflector 110, and a change in the digital image evaluation.

Between steps 8 and 9, there may optionally be a switchover from a second operating method for acquiring the complex multi-beam effect to the first mode of operation for a quick and high-resolution image capture of a portion of an object surface in a step STU.

Hence, a method for determining a complex multi-beam effect 41 comprises recording an image of a time-averaged inspection image of the raster arrangement 41 of the multiplicity of particle beams 9 using a detector camera 207 by scanning a portion of a structured surface 25 of a wafer 7 and averaging out an image contrast of the surface structure of the wafer 7, and analysing the inspection image for the purposes of determining at least one deviation of the raster arrangement 41 of the incidence locations of the plurality of particle beams from a predefined or ideal raster arrangement 45 and a change in the shape and size of the focal points 15 of the particle beams.

In an example, averaging out the image contrast is achieved by quickly scanning the portion of the surface 25 of the wafer 7 with an image recording time of T1<T2, such as less than T1<T2/10, for example T1<T/100, where T2 corresponds to the time for recording an image of the portion of the surface 25 with a high spatial resolution and a pixel dimension of 2 nm, 1 nm or less. T1 is typically less than 100 ms, such as less than ms. In an example, the averaging out of the image contrast of the surface structure of the wafer 7 is implemented by averaging the detection signal over time.

It was found that multi-beam effects as a result of an inhomogeneous extraction field occur at the edges of an object in particular. By way of example, electrons are deflected in the direction of the wafer edge. FIG. 6 shows an example. A plurality of focal points are formed in an image field 17 in the vicinity of an edge 43 of a wafer 7 by the plurality of primary beams 3a. A counter electrode 151 forms the lower termination of the objective lens unit 102 and is at a voltage V1. By way of example, the voltage V1 can be at earth potential or be at V1=3 kV. The voltage difference between the wafer surface 25 and the counter electrode 151 is typically between 20 kV and 35 kV, for example 30 kV. By way of example, the wafer is at a voltage of −27 kV.

The objective lens unit comprises a solenoid 149 for forming a focusing magnetic field for the purposes of focusing the primary beams on the wafer surface 25. A voltage V2 ranging from 1 kV to 4 kV, for example 2 kV, is supplied to the wafer 7 or wafer surface by way of the wafer reception area 505 in the displacement stage 500. An extraction field 113a forms between the counter electrode 151 and the wafer surface 25 by way of the voltage difference V2−V1. The extraction field 113 typically has a field strength of 1-5 kV per mm at the wafer surface 25, as a result of which the primary electrons 3 are decelerated. In this case, the wafer reception area 505 is insulated with respect to the wafer stage 500 and the wafer stage 500 is at earth potential or 0 kV. The extraction field 113a is illustrated schematically by way of equipotential surfaces. However, there is a height difference DW at the edge 43 of the wafer 7 and the equipotential surfaces no longer extend parallel to the surface 25 of the wafer 7 in the vicinity of the edge 43 of the wafer, and the primary beams 3a are deflected. As a consequence of the inhomogeneous edge field, the raster arrangement of the primary beams therefore experiences a distortion similar to the distortion depicted in FIG. 5C. Additionally, further effects may occur. According to a second embodiment of the disclosure, the effects in the edge region are compensated by an additional electrode in the periphery of the wafer 7. The second embodiment is illustrated in FIG. 7. A correction electrode 153 that is supplied with a voltage V3 and insulated from the reception area 505 by way of an insulation 155 is arranged in the periphery around the wafer 7. A correction field is generated in the periphery around the wafer 7 by way of the voltage V3, and a homogenization of the extraction field 113b is obtained. The correction electrode 153 has a distance G from the wafer 7 and a height DE above the wafer reception area 505. The distance G may vary over the perimeter of the wafer. The strength of the voltage V3 is set on the basis of a different thickness DW of the wafer 7, a local distance G between the wafer edge and the correction electrode 153, and the distance 47 between the inspection position 35 and the wafer edge 43 such that an inhomogeneity of the extraction field 113b is minimized. In this case, the thickness DW of the wafer 7 is approximately 0.7 mm, with a deviation of approximately 50 μm to 100 μm. By way of example, the height DE of the electrode 153 is less than the thickness DW of a wafer 7, and the difference of the correction voltage V3 vis-a-vis the voltage V1 is chosen to be greater than the difference of the voltage V2 vis-a-vis the voltage V1. By way of example, the thickness is chosen DE<0.5 DW or even less. By way of example, V3 is set between −2 kV and −4 kV. By way of example, the wafer 7 is at an absolute value of a voltage difference of |V1−V2|=28 kV vis-a-vis the counter electrode 151. By way of example, the correction electrode 153 is at an absolute value of a voltage difference of |V2−V3|=3−6 kV vis-a-vis the wafer 7. The voltage difference V2−V3 is set such that it forms an additional field contribution form between wafer edge 43 and electrode 153, the effect of the field contribution is illustrated by the additional equipotential line 113c. This field contribution ensures smoothing and a homogenization of the extraction field 113b between the wafer surface 25 and objective lens 102. Ideally, the distance G is chosen to be as small as possible, for example 0.5 mm or 0.2 mm or less. For an unchanging extraction field 113b, the wafer 7 is desirably centred very accurately and without variation in thickness DW along the perimeter. A local deviation of the thickness DW, of the height DE of the correction electrode and a local deviation of the distance G can be taken into account for each inspection position by an optimal and adjusted setting of the correction voltage V3. In general, a correction voltage for a homogeneous extraction field can be set on the basis of a distance of an inspection position from a wafer edge. In an embodiment, the correction voltage of the continuous correction electrode is adjusted locally to the current inspection position on the basis of the evaluation of the inspection images of the raster arrangement, for example on the basis of a preceding inspection position in the vicinity of the wafer edge.

FIG. 8 illustrates the third embodiment of the disclosure. In the third embodiment, the correction electrode 153 is embodied in a plurality of segments, for example in eight segments 153.1 to 153.8. Further, the counter electrode 151 is embodied in a plurality of segments, for example in eight segments 151.1 to 151.8. An extraction field that is as homogeneous as possible is obtained by way of supplying the segments of the correction electrode 153.1 to 153.8 or the segments of the counter electrode 151.1 to 151.8 with for example eight different voltages. A voltage V3.2 for the correction electrode 153.2 is depicted in exemplary fashion. In the second and third embodiment, the control unit 800 is configured to make available both the sample voltage V2 and at least one correction voltage V3, V3.2 for at least one correction electrode 153, 153.2 by way of the voltage supply unit 503, in order to bring about a homogenization of the extraction field. Further, the control unit 800, in particular the control unit of the illumination device 830, is configured to supply at least one counter voltage 151 to the objective lens system 102 in order to bring about a homogenization of the extraction field. The sample voltage V2, at least one counter voltage V1 and the at least one correction voltage V3 or V3.2 form quickly changeable parameters for driving the multi-beam system 1.

An embodiment of the disclosure therefore comprises a displacement stage 500 for a multi-beam microscope 1 and a multi-beam microscope 1 having the displacement stage 500 with a reception area 505 for receiving a wafer 7 with an edge 43 and a diameter D, by which a voltage V2 can be applied to the wafer 7 during operation. Further, a ring-shaped electrode 153 is arranged on the displacement stage 500 in the periphery of the reception area 505. The ring-shaped electrode 153 has an internal diameter DI>D such that, when the wafer 7 is received, a distance is formed between the edge 43 of the wafer 7 and the ring-shaped electrode 153. The ring-shaped electrode 153 is insulated from the reception area 505 so that a voltage V3 can be applied to the ring-shaped electrode 153 during operation. In an example, the ring-shaped electrode 153 is formed from a plurality of mutually insulated electrode segments, for example two, four, eight or more, to which at least one first voltage V3 can be applied.

Many effects related to imaging with a multi-beam microscope are linked very strongly to the topological conditions. As illustrated on the basis of FIG. 6, the edge 43 of a wafer 7 or of an object generally has a significant influence. Since the relative position of the inspection positions with respect to the edge 43 of the wafer 7 is known in advance in the context of the wafer inspection in particular, the improved adjustment of both the detection path and the illumination path, including the homogeneous extraction field 113, dependent on a distance of an inspection position from an edge of the wafer can already be implemented when homing in on the inspection site. In the fourth embodiment, a multi-beam system and a method for operating the multi-beam system are provided, within the scope of which parameters of components of the illumination path and of the detection path of the multi-beam system are set dependent on a distance of an inspection position from an edge or boundary of an object. A control unit 800 of the multi-beam system 1 is configured to determine the distance of an inspection position from a boundary or edge 43 of the object. The control unit 800 is further configured to determine a complex multi-beam effect from the distance and the current working point of the multi-beam system 1. Further, the control unit 800 is configured to determine parameters for operating the multi-beam system 1 at the inspection site, the parameters being suitable for reducing or completely compensating the complex multi-beam effect. Further, while carrying out the inspection task using the multi-beam system 1 at the inspection position, the control unit 800 is configured to drive components of the illumination system 100 and of the detection system 200, including the extraction field 113, of the multi-beam system 1 using parameters, and to supply a sample voltage V2 and at least one correction voltage V3 to electrodes on the displacement stage 500 as additional parameters, the parameters in combination being suitable for reducing or completely compensating the complex multi-beam effect.

The second and third embodiment of the disclosure thus describe a displacement stage 500 with a reception area 505 for receiving a substantially planar object 7 with an edge 43, a thickness DW and an external diameter D, and a ring-shaped electrode 153 with a height DE over the reception area 505, the latter being arranged in the periphery of the reception area 505 and having an internal diameter DI>D such that, when an object 7 is received, a distance G is formed between the edge 43 and the ring-shaped electrode 153. In this case, the electrode 153 is insulated from the reception area 505 so that a different voltage difference can be applied to the ring-shaped electrode 153 during operation.

The second and third embodiment further describes a multi-beam system comprising the displacement stage 500 and a measuring device for determining an edge effect, and a control unit configured during operation to supply a first voltage V2 to a received object and a second voltage V3 at the ring-shaped electrode for reducing the edge effect, for the purposes of generating the voltage difference.

In the third embodiment, the electrode 153 has available a plurality of segments 153.1 to 153.8, to which a plurality of different voltages V3.1 to V3.8 can be applied. In a further embodiment, the objective lens system 102 of the multi-beam system 1 according to the third embodiment has available a plurality of counter electrodes 151.1 to 151.8, to which a plurality of different voltages V1.1 to V1.8 can be applied. The voltage supply of the electrodes is designed in this way in order to generate, together with the object voltage, a homogeneous extraction field 113 between the objective lens system 102 and the surface of the object.

It was found that a number of complex multi-beam effects depend on the inspection position on the surface 25 of a wafer and are therefore, in principle, known in advance. An improved method, based thereon, for operating a multi-beam system 1 is depicted in FIG. 9. Using the method, parameters for operating the multi-beam system 1 are optimally set, for example parameters of components of the illumination system or illumination path 100, of the detection system or detection path 200 and of the sample voltage or correction voltage for the homogeneous extraction field 113. In combination, the parameters for operating the multi-beam system 1 are suitable for reducing or completely compensating the complex multi-beam effect at an inspection position. In a first step SI, a wafer 7 is received on the wafer reception area 505 of the displacement stage 500, and a coordinate system of the wafer 7 is registered. A list of inspection tasks is acquired and a first inspection task, for example, is carried out. To this end, the first inspection position of the wafer 7 is centred with respect to the optical axis 105 of the multi-beam system 1 and the surface 25 of the wafer 7 is aligned in the setting plane or focal plane 101 of the multi-beam system 1. The method for operating a multi-beam system 1 is now illustrated in exemplary fashion for the second or next inspection task; however, this can be any inspection task, in particular the first inspection task as well.

A complex multi-beam effect for a next inspection task is predicted in a next step SE. The prediction of the complex multi-beam effect may be put together from a plurality of components and the complex multi-beam effect may be caused by a plurality of causes. Complex multi-beam effect denotes the effects illustrated in the context of FIG. 5, which comprise both a deviation of a raster arrangement of the plurality of primary beams or secondary beams from a predefined raster arrangement and the deviation of at least one shape or size of a focal point of a primary beam or of a secondary beam, for example of three or all primary beams or secondary beams.

In step SER, a complex multi-beam effect VKR is predicted from a distance of an inspection position from an edge 43 of a wafer 7. In general, the position of the inspection site in relation to the sample edge 43 is information known in advance. Consequently, it is possible to take account of distortions of the raster arrangement 41 by way of edge effects and distortions as a result of inhomogeneous charging.

An example of the method according to the fourth embodiment contains the detection and storage of parameters for an improved adjustment of the detection path and illumination path and the setting of the voltages for a homogeneous extraction field for different inspection sites on the basis of a distance from an edge of an object. Then, the optimal parameters of an improved adjustment of both the detection path and the illumination path, including the setting of the voltages for a homogeneous extraction field, are determined and set dependent on a next inspection site from the predetermined and stored parameters during a wafer inspection.

In step SED, a complex multi-beam effect VKA is predicted from a priori information about the inspection position, for example from design information, CAD information or preceding measurements.

In the fifth embodiment, a multi-beam system and a method for operating the multi-beam system are provided, within the scope of which parameters of components of the illumination path and of the detection path and voltages for a homogeneous extraction field of the multi-beam system are set dependent on a priori information. In an example, the determination of the composition of the object at least at the next inspection position is implemented in step SED. In this case, the determination of the composition of the object comprises the determination of the material composition of the object, for example from CAD information about the semiconductor structures formed in a wafer at the inspection position. By way of example, possible inhomogeneous or local charging effects of the object 7 may be determined from CAD information. On the basis of the composition there is a determination of expected complex multi-beam effects and a setting of parameters of the multi-beam system which are suitable for reducing or completely avoiding the complex multi-beam effect. In an alternative example, the a priori information consists of information from earlier inspections at similar inspection sites, for example on other wafers.

Preceding measurements form further a priori information. By way of example, charges may arise due to preceding measurements and may only dissipate slowly by way of leakage currents. The charging of already scanned, adjacent inspection sites leads to distortions in the raster arrangement and this information may be considered when determining the cause for the deviations. In step SEH, a complex multi-beam effect VKS is predicted from information from preceding inspection tasks, for example a detection of a current state of the multi-beam system 1, or from expected charging effects of the wafer from preceding measurements at preceding inspection positions. In this case, for example the position and the distance of the next inspection position in relation to the preceding inspection positions can be determined and evaluated. Additionally, the time difference to previous inspection tasks can be evaluated in order to take account of discharging effects from preceding sample charging.

It was found that a number of further complex multi-beam effects depend on adjacent inspection position on the surface 25 of a wafer and are therefore, in principle, known in advance. In the sixth embodiment, a multi-beam system and a method for operating the multi-beam system are provided, within the scope of which parameters of components of the illumination path and of the detection path including the voltages for a homogeneous extraction field 113 of the multi-beam system are set dependent on adjacent inspection positions or preceding inspection tasks. In one example, the multi-beam system comprises a control unit to this end, which control unit determines for example a current charge distribution of the object at an inspection position caused by preceding inspections on the same object, prior to measurement or inspection at the inspection position. In an example, step SEH includes determining a current charge distribution of the object surface at the inspection position caused by preceding inspections on the same object. By way of example, regions of a wafer may be conductively connected and scatter charging effects beyond an inspection site. By way of example, regions of a wafer may comprise capacitances which store charging effects over a relatively long period of time. On the basis of the current charge distribution there is a determination of expected complex multi-beam effects and a setting of parameters of the multi-beam system which are suitable for reducing or completely avoiding the complex multi-beam effect. A special example is formed by a method of repeatedly homing in on the same inspection position on the same wafer.

In step SEC, the predictions VKR, VKA or VKS from distance of the inspection position from the edges, a priori information or information from preceding inspection tasks are combined, and a combined complex multi-beam effect VKK is predicted.

Optimized parameters for driving the multi-beam system 1 are determined in step PE. Proceeding from a working point AP of a multi-beam system 1, the multi-beam system is operated using a certain set of parameters. The parameters of the working point AP for example describe currents or voltages of electromagnetic or electrostatic components, for example for setting a beam current, a beam pitch or a predefined magnification, a scanning program, the size of an extraction field, or a focal position.

In step PEI, the standard parameters according to the working point AP are determined in accordance with the next inspection task at an idealized inspection position.

In step PEC, a change in at least one parameter value of a parameter is determined from the predicted complex multi-beam effect VKK. Examples of parameter changes that are suitable for minimizing a complex multi-beam effect are listed further above in conjunction with the first embodiment of the disclosure. By way of example, the determination is implemented on the basis of previously determined and stored optimal parameter values, from which the changes in the parameter values are determined by interpolation for example.

In step PC, the current parameters PA according to the working point AP and including the parameter changes in step PEC are transmitted in accordance with the next inspection task at the next inspection position, and the multi-beam microscope 1 is driven using the determined parameter values.

In step IN, the next inspection task at the next inspection position is implemented. To this end, the next inspection position of the wafer 7 is centred with respect to the optical axis 105 of the multi-beam system 1 and the surface 25 of the wafer 7 is aligned in the setting plane or focal plane 101 of the multi-beam system 1. The multi-beam system 1 is operated with the current parameter values PA and the inspection task is carried out. By way of example, an image portion of the wafer surface at the inspection position is captured with a high resolution and imaging fidelity of better than 5 nm, better than 2 nm or even better than 1 nm.

Simultaneously with step IN, the raster arrangement of the secondary particle beams and the shape or the size of at least one focal point of a secondary beam path is monitored in step M. Monitoring is implemented by way of acquiring a time-averaged signal of the spatially resolving detector 207 of the multi-particle system 1. As a result of time-averaging during a scanning of the object surface 25, areal averaging of the signal of the secondary particles over a plurality of object structures on the object surface 25 is achieved, and the current raster arrangement of the secondary particle beams and the shape or the size of at least one focal point of a secondary particle beam can be detected reliably with a high accuracy of less than 1 nm. The capture of the current raster arrangement of the secondary particle beams and the shape or the size of at least one focal point of a secondary particle beam can be implemented multiple times during an inspection task, for example ten times or one hundred times.

In step Q, a current complex multi-beam effect is determined from the monitoring result of step M. Should a current complex multi-beam effect during an inspection task exceed a predetermined threshold, there is a signal to step PE to continually change or update the setting parameters of the multi-beam system 1 and step PE is repeated during the inspection task of step IN. By way of example, this therefore also allows the method of driving both the detection path and the illumination path, including the voltages for a homogeneous extraction field, to be used for a fast autofocus. In general, this allows the method of adjusting both the detection path and the illumination path to be used for a dynamic correction. In respect of a dynamic correction, reference is made to the international patent application WO 2021239380 A1, which is hereby incorporated in the disclosure by reference.

In step ES, the result, for example the digital image of the portion of the wafer surface at the inspection position, is finally stored. In the example, the digital image information is stored together with the ongoing information from monitoring step M. The ongoing information about the raster arrangement of the secondary particle beams and the shape or the size of at least one focal point of a secondary particle beam is taken into account in a subsequent step DV of digital image processing and data evaluation.

An improved adjustment of both the detection path 11 and illumination path 13, including the settings of the voltages for a homogeneous extraction field 113, is facilitated for a specific inspection position of a surface 25 of an object 7 using the multi-beam system 1 according to the first embodiment and the methods for using the multi-beam system 1 according to FIG. 9. A method for determining the improved parameters for setting the multi-beam system 1 at a working point AP for carrying out an inspection task is described in a seventh embodiment. The method is based on the basis of acquiring and evaluating two fundamentally different information items about the multi-beam microscope and the interaction with an object. Firstly, the raster arrangement 41 of the plurality of secondary beams 9 is detected and evaluated. Secondly, the shape and size of the at least one focal point 15 of the secondary beams 9 is detected and evaluated. It is also possible to evaluate shapes and sizes of a plurality of focal points 15, for example of at least three focal points, of the secondary beams 9. Together, these deviations are referred to as complex multi-beam effect.

Both information items are acquired during scanning imaging of a portion of a surface 25 of an object 7. In this case, a plurality of J focal points 5 of J primary beams 3 are moved in scanning fashion over the surface 25 of the object 7 and a plurality of J scan positions on the object surface 25 are illuminated at the same time. To this end, a first deflection unit 110 for scanning deflection of the plurality of J primary beams 3 is situated in the primary path or illumination path 13. Each incidence location of the J focal points 5 of the J primary beams 3 forms a source location for secondary electrons, which are collected and imaged on a detector 207, during the short period of time of scanning irradiation using the J primary beams 3. The plurality of the J source locations of the secondary electrons move synchronously over the object surface in accordance with the scanning irradiation using J primary beams. Therefore, a second deflection unit 222 for scanning deflection of the J secondary beams 9 that emanate from the J source locations is situated in the imaging path of the secondary electrons, which is also referred to as detection path or secondary path 11, so that the focal point 15 of the J secondary beams on the detector remain at J same detection locations. In this case, the second deflection unit 222 in secondary path is synchronized with the first deflection unit 110 in the primary path.

A plurality of J time-sequential data streams which are converted into a plurality of J two-dimensional digital image information items are acquired as a result of the scanning illumination with the plurality of J primary beams 3 and the acquisition of the signals of the plurality of J secondary beams 9 synchronously with the scanning illumination. Each image information item represents the spatially resolved rate of generation of secondary electrons by the spatially resolved illumination of the object surface 25 by a focal point 5 of a primary beam 3. In this case, the rate of the generation of secondary electrons depends on the local surface condition, for example the local material composition of a structured wafer surface. The information about the shape and size of the focal points themselves and the raster arrangement 41 of the focal points for adjusting both the detection path and the illumination path are acquired in time-averaged fashion such that the influence of the structuring of the object surface is reduced by averaging over a plurality of scan positions on the surface. Consequently, the method is rendered possible for a plurality of objects, and there is no need for special measurement or calibration objects. In particular, the method of adjusting both the detection path and the illumination path may also be implemented during an inspection task at an inspection position on an object surface.

In an example of the method there is an assignment of selected setting parameters to assigned inspection positions, and a storage of the assignment. A wafer inspection method then comprises homing in on a next inspection position in step SI, followed by determining, on the basis of the next inspection position, setting parameters of the multi-beam microscope for optimal imaging at the inspection position in step SE, and the setting of the determined setting parameters in a step PE. In this case, step SE further includes loading predefined setting parameters of the multi-beam microscope, which are assigned to at least one inspection position. In an example, step SE comprises determining predefined setting parameters of the multi-beam microscope at the next inspection position. In an example, there is an interpolation of the setting parameters for optimal imaging at the next inspection position from at least two setting parameters which are assigned to two adjacent inspection positions. The method can therefore be suitable for repeatedly inspecting objects, in particular portions of surfaces 25 of wafers 7, at repeated or similar inspection positions.

In a further embodiment there is an optimization of inspection positions on the basis of predefined different setting parameters of the multi-beam microscope, which are each assigned to an inspection position. Consequently, it is possible to prevent frequent changes to setting parameters of the multi-beam microscope 1. By way of example, there is an optimization of the sequence of inspection positions on the basis of predefined different setting parameters of the multi-beam microscope, which are each assigned to a number of inspection positions. By way of example, there is an optimization of the sequence of inspection positions on the basis of local charging effects. In one case, successive inspection positions can be arranged adjacent in a targeted manner in order to have long-term compensation of pre-existing local charges. In another case, successive inspection positions could be arranged with maximum spacing in a targeted fashion, in order to allow local charges responsible for charging effects to be discharged for as long as possible by way of leakage currents.

A wafer inspection method using a multi-beam system 1 having a plurality of primary and secondary particle beams (3, 9) includes the following steps:
receiving a wafer 7 using a displacement stage 500,
determining a sequence of inspection tasks at a succession of inspection positions (33, 35) on a surface 25 of the wafer 7,
on the basis of an inspection position (33, 35) of an inspection task, determining setting parameters of the multi-beam system 1 for the purposes of optimal imaging at the inspection position (33, 35),
changing the setting parameters of the multi-beam system 1 to the determined setting parameters of the inspection task,
carrying out the inspection task by scanning the inspection position (33, 35) with a high resolution and an image recording time T2>100 ms.

In an example, the step of determining setting parameters comprises homing in on the inspection position (33, 35) and recording an image of a time-averaged first inspection image of the raster arrangement 41 of the plurality of secondary particle beams 9 using a detector camera 207 by quickly scanning the inspection position with an image recording time of T1<T2, such as T1<T2/100 or T1<T2/1000. The first inspection image is analysed to determine a complex multi-beam effect and setting parameters are determined therefrom such that the complex multi-beam effect is at least partly compensated.

In an example, the step of determining setting parameters further comprises homing in on a reference position and recording an image of a time-averaged first reference image of the raster arrangement 41 of the plurality of secondary particle beams 9 using the detector camera 207 by quickly scanning the reference position with an image recording time of T1. The analysis of the first inspection image of the raster arrangement 41 contains a comparison with the reference image of the raster arrangement 41. The reference position may be a preceding inspection position or a reference position on a reference object which is additionally arranged on the displacement stage 500.

In an example, the method may include recording a further image of a time-averaged second inspection image of the raster arrangement 41 by quickly scanning the inspection position (33, 35) using the determined setting parameters. A success of the compensation can be determined from the analysis of the second inspection image. A residual complex multi-beam effect can be determined and there can be a renewed determination of improved setting parameters such that the residual complex multi-beam effect is at least partly compensated. The determined setting parameters can be assigned to an inspection position (33, 35) and can be stored such that there can be repeated inspection, for example of at least one second wafer, at the same inspection position (33, 35) using the setting parameters assigned to the inspection position (33, 35). In general, predefined or stored setting parameters of the multi-beam microscope 1 can be used for a wafer inspection task. In an example, the setting parameters can be determined by interpolating at least two predefined or stored setting parameters at at least two adjacent reference positions. Further, at least one information item known in advance can be considered when determining the setting parameters, the information known in advance containing CAD information about composition of the wafer 7 at an inspection position (33, 35) in addition to the information from preceding measurements at the inspection position (33, 35) or at adjacent inspection positions (33, 35). Additionally, the method may comprise determining a distance of the inspection position (33, 35) from an edge of the wafer 7.

Within the scope of optimizing the sequence of inspection tasks, a determination of a sequence of setting parameters of the multi-beam system 1 for optimal imaging for each of a sequence of inspection positions (33, 35) may be altered such that the number of changes in the setting parameters of the multi-beam system 1 is minimized.

Determining the parameters of an improved adjustment of both the detection path and the illumination path, including the setting of the voltages for a homogeneous extraction field, dependent on an inspection site is implemented iteratively in an example. The method is illustrated in FIG. 10. The first step SI is identical to step SI according to FIG. 9. Following step SI, an image is taken M1 without corrections or changes to the parameters at a next inspection position in step SM. The deviation of the raster arrangement 41 of the plurality of secondary beams 9 from a predefined or expected raster arrangement is detected and evaluated, and the deviation of the shape and size of at least one focal point 15 from a predefined or expected shape and size of the focal point is detected and evaluated at the same time. Typically, a deviation of the shape and size of at least three focal points 15 from a predefined or expected shape and size of the three focal points 15 is detected. As described above 3, the deviations are detected within the scope of time averaging during the scanning of the object surface 25 with the plurality of primary beams 3 in order to eliminate influences of the composition of the object 7.

During an inspection step IN, the raster arrangement 41 is displaced synchronously over an object surface 25, and image data of an object surface 25, for example of a wafer, are acquired. The anti-scan using the deflection device 222 ensures that the raster arrangement 41 remains fixed in position or stationary on the detector 207. This parallel acquisition of the plurality of J image data points is implemented at a scanning frequency FS of for example 100 MHz; further examples of conventional scanning frequencies are specified above.

In an example, the scanning frequency is increased during the step M1. By way of example, a scanning frequency FS can be increased by a factor of 10, from for example 50 MHz to 500 MHz, or from 100 MHz to 1 GHz. An averaging of the data recording is implemented over larger focal regions on the object surface 15 as a result of the increased scanning frequency.

A probable cause for the deviation is determined in step Q1 from the deviations. In step PE, suitable parameters for adjusting illumination path and detection path, including the voltages for a homogeneous extraction field 113, are determined. The detection of the various deviations, specifically the deviation of the raster arrangement 41 of the plurality of secondary beams and of the shape and size of the focal points 15, allows more targeted conclusions to be drawn about the cause, for example whether there is a disruption in the illumination path 13 and a deviation of the plurality of focal points 15 of the primary beams 3 is already present on the object surface 25 or whether an edge 43 or topography of the object 7 is a cause for the deviation, whether global or local charging effects are present, or whether there is a disruption in the detection path 11.

In step ZS, further information, for example from additional detectors, or a priori information can be used to determine the probable cause of the deviations. Further detectors may comprise a distance sensor for determining the distance of the sample surface from a reference area. The use of such a distance sensor for example allows a better distinction to be made between global charging of the object 7 and purely mechanical defocusing. Further examples comprise field sensors for measuring an electric or magnetic field strength in the vicinity of the object surface 25. A priori information is described above in the context of FIG. 9 and may comprise CAD information about the inspection position, or stored information from earlier measurements of similar objects or similar inspection sites.

After the probable cause of the deviations has been determined, correction measures or an adjustment of detection path and illumination path, including the voltages for a homogeneous extraction field, are/is determined in step PE. Steps SM and PE may also be carried out multiple times in iterative fashion. By way of example, a fine correction is calculated in a second step. Finally, the multi-beam system is driven with the altered parameters in step IN and the inspection is carried out at the same inspection site.

Simultaneously with the inspection step IN, the determination of the deviations can be repeated in step M again. Should the deviation exceed a predetermined tolerance limit, the determination of the cause in step Q and the determination of the new parameters for adjusting the detection path and illumination path is repeated. Above-described steps ES and DV follow.

In a further example of the seventh embodiment, the method for setting a multi-beam microscope for inspecting objects comprises a variation of the steps listed above. In step SM, an image of a time-averaged first reference image of the raster arrangement of the plurality of primary beams is initially taken using a detector camera by quickly scanning a reference position of the object within a first period of time T1, which for example is shorter than a second period of time T2 by a factor of 10 or 100, 1000 or 10 000, the second period of time corresponding to the period of time for recording a high-resolution image of a portion of the surface of the object. By way of example, the first period of time T1 can be 1 ms to 100 ms. By way of example, the second period of time T2 can be approximately 0.8 s, is or more.

An image of a time-averaged, second inspection image of the raster arrangement of the plurality of primary beams is recorded using the detector camera by quickly scanning the inspection position within T1 of for example 1 ms to 100 ms. The second inspection image of the raster arrangement is compared to the first or reference image of the raster arrangement and the deviations or differences of the raster arrangement vis-a-vis the reference image are analysed in a step Q1 or step Q. In step PE, there is a determination of changes of selected setting parameters of the multi-beam microscope for adapting the multi-beam microscope to the inspection site. The changes of the selected setting parameters are carried out as correction measures. Following the implementation of the correction measures, the method may additionally include renewed recording of an image of a time-averaged second reference image of the raster arrangement of the plurality of primary beams using the detector camera by quickly scanning the inspection position within 1 ms to 100 ms, and a renewed analysis and determination of optimized setting parameters of the multi-beam system. In step IN, an inspection image of the surface 25 of the object 7 is recorded with a high spatial resolution by slowly scanning the inspection position within 100 ms to 2000 ms, for example. In this case, the selected setting parameters may comprise at least one of the following parameters:
realignment of the wafer 7 using a displacement stage 500;
driving electrodes (151, 153, 505) for influencing a field profile of an extraction field 113 at the surface 25 of the wafer 7;
driving a beam deflector (107, 110, 222) for compensating an offset of the raster arrangement 41;
changing a working point of the multi-beam system for the purposes of adjusting a scale of the raster arrangement 41;
changing a digital image evaluation.

Method of setting a multi-beam system 1 for inspecting a wafer 7 hence includes the following steps:
recording an image of a time-averaged first reference image of a raster arrangement 41 of a plurality of particle beams using a detector camera 207 by quickly scanning a reference position on a wafer 7 within a first time T1;
homing in on an inspection position (33, 35);
recording an image of a time-averaged first inspection image of the raster arrangement 41 of the plurality of particle beams at an inspection position (33, 35) using the detector camera 207 by quickly scanning the inspection position (33, 35) within the first time T1;
analysing the first inspection image of the raster arrangement 41 and the first reference image of the raster arrangement 41 and deriving selected setting parameters for adjusting the multi-beam system 1 for the purposes of optimal imaging at the inspection site (33, 35);
setting the multi-beam system 1 using the selected setting parameters;
recording an inspection image of the surface 25 of the wafer 7 with a high spatial resolution by slow scanning of the inspection position (33, 35) in a second time T2, where T1<T2, such as T1<T2/10, for example T1<T2/100.
Optionally, for verifying the success of the altered adjustment parameters, an image of a time-averaged second reference image of the raster arrangement 41 of the plurality of primary beams may be recorded again using the detector camera 207 by quickly scanning the reference position within the first time T1 after setting the multi-beam system 1 with the selected setting parameters. Rather than at the reference position, the renewed image can be recorded for a time averaged, second inspection image of the raster arrangement 41, even at the inspection position (33, 35).

The causes of the deviations of the raster arrangement and of the shape and size of beam focal points may be subject to a dynamic change. By way of example, global charging of a sample increases when the illumination by the plurality of primary beams increases and may lead to an increasing deviation of the raster arrangement while imaging. Such dynamic effects are determined in an eighth embodiment of the disclosure and for example the speed of a change or deviation of the raster arrangement and of the shape and size of beam focal points is taken into account. This allows the deviations of the raster arrangement and of the shape and size of beam focal points to be corrected dynamically and allows the parameters for adjusting the detection path and illumination path to be dynamically altered in predetermined fashion during the capture of an image portion of the object surface. An example is illustrated in FIG. 11. FIG. 11A shows a time-varying charging effect, which for example at the edge of a wafer leads to a distortion and an offset of the raster arrangement. Before an inspection task is carried out, there already is a charge 903 from preceding inspection tasks, with the charge slowly decreasing as a result of discharging effects. With the start of the image data acquisition at the time t0, renewed charging 905 of the object surface 25 starts at the same time as a result of the illumination of the wafer surface with the plurality of primary beams and the release of secondary particles from the object surface 25. The charging may also transitioning to saturation towards the end of an image data capture at the time t1. A complex multi-beam effect grows in parallel with the charging. The complex multi-beam effect may for example be compensated at least in part during the period of time Ts of the inspection task by suitable synchronous driving of the quasi-static deflector 107. To this end, a control signal as a changeable parameter for the quasi-static deflector 107 is determined from the expected time profile of the charge 905, and is supplied to the quasi-static deflector 107. An example of a synchronous control signal 907 is shown in FIG. 11B.

To measure the raster arrangement of the plurality of secondary beams and at least one shape or size of a focal point of a secondary beam, the disclosure uses a time-averaged measurement signal which can be acquired during an inspection task. In this case, the measurement can be carried out by the same detector that is also used for high-resolution imaging, with the time averaging carried out as described above being set by way of the sampling rate of the analogue-to-digital converter or the scanning frequency or both. Alternatively, in the case of a detection system which initially converts the signals of the secondary electrons into light by way of a scintillator, a beam divider or deflector may be inserted in the light optical unit disposed downstream of the converter and steer at least a fraction of the generated light onto a CMOS camera. CMOS cameras typically have a lower refresh rate of for example 10-100 frames per second, and so averaging is obtained by the reduced refresh rate. Alternatively, the electron-optical path may be split in the projection optical unit 205 in a ninth embodiment, for example by way of a modified deflection system 224. FIG. 12 shows a detection system of a multi-beam system 1 with a projection optical unit 205 that contains a beam deflector 224. During an image capture, the beam deflector 224 is set such that the plurality of J secondary electron beams 9 are steered in the direction of a first detector 207a, on the detection area of which focal points 15a are formed. By way of example, the detector 207a may comprise a very sensitive photodiode array with exactly one photodiode for each of the J secondary beams. To detect the raster arrangement and the shape and size of the focal spots, the plurality of J secondary beams are steered in the direction of the second detector 207b using the deflector 224, the second detector for example being able to be formed by a high resolution CMOS camera with a scintillator layer. There, the raster arrangement and the shape and size of the focal points 15b can be detected with a high resolution. The imaging scales in the two detection arms may be set differently in the process via the lenses 201a and 210b and via the spacings such that, for example, the illumination of the second detector 207b is matched to the diameter of the second detector 207b. In this case, the switchover between projection systems 205a and 205b can be implemented very quickly by way of an electrostatic deflector 224.

The disclosure can be described by following clauses. The disclosure is, however, not limited to the clauses:
Clause 1: A wafer inspection method using a multi-beam system (1) having a plurality of particle beams (3, 9), the method including the following steps:
   receiving a wafer 7 using a displacement stage 500,
   determining a sequence of inspection tasks at a succession of inspection positions (33, 35) on a surface (25) of the wafer (7),
   on the basis of an inspection position (33, 35) of an inspection task, determining setting parameters of the multi-beam system (1) for the purposes of optimal imaging at the inspection position (33, 35),
   changing the setting parameters of the multi-beam system (1) to the determined setting parameters of the inspection task at the inspection position,
   carrying out the inspection task by scanning the inspection position (33, 35) with a high resolution and an image recording time T2>100 ms.
Clause 2: The method according to Clause 1, wherein the step of determining setting parameters comprises the following steps:
   homing in on a first inspection position (33, 35),
   recording an image of a time-averaged first inspection image of a raster arrangement (41) of the plurality of particle beams (3, 9) using a detector camera (207) by quickly scanning the inspection position with an image recording time of T1<T2, such as T1<T2/100 or T1<T2/1000,
   analysing the first inspection image for the purposes of determining a complex multi-beam effect, the complex multi-beam effect comprising a distortion of the incidence locations (5, 15) of the plurality of particle beams (3, 9) and a change in a shape and a size of focal points (5, 15) of particle beams (3),
   determining setting parameters such that the complex multi-beam effect is at least partly compensated at the first inspection position (33, 35).
Clause 3: Method according to Clause 2, wherein the step of determining setting parameters further comprises:
   homing in on a reference position,
   recording an image of a time-averaged reference image of the raster arrangement (41) of the plurality of particle beams (3, 9) using the detector camera (207) by quickly scanning the reference position with an image recording time of T1, the step of analysing the first inspection image of the raster arrangement (41) comprising a comparison with the reference image of the raster arrangement (41).
Clause 4: Method according to Clause 2 or 3, further comprising:
   recording an image of a time-averaged second inspection image of the raster arrangement (41) by quickly scanning the first inspection position (33, 35) using the determined setting parameters,
   analysing the second inspection image for the purposes of determining a complex multi-beam effect,
   redetermining improved setting parameters such that the complex multi-beam effect is at least partly compensated.
Clause 5: Method according to any one of the preceding clauses, further including:
   assigning the determined setting parameters to the first inspection position (33, 35) and storing the assignment of the setting parameters.
Clause 6: Method according to Clause 5, further comprising the repeated inspection of at least one second wafer at the first inspection position (33, 35) using the setting parameters assigned to the first inspection position (33, 35).
Clause 7: Method according to Clause 1, further including:
   loading predefined setting parameters of the multi-beam microscope (1), with the predefined setting parameters being assigned to a respective reference position on a wafer, the setting parameters for the inspection position (33, 35) being determined from the predefined setting parameters.
Clause 8: Method according to Clause 7, wherein the setting parameters are determined by interpolating at least two predefined setting parameters at at least two adjacent reference positions.
Clause 9: Method according to Clause 1, wherein the determination of the sequence of inspection tasks comprises the following steps:
   determining a sequence of setting parameters of the multi-beam system (1) for the purposes of optimal imaging at each of the inspection positions (33, 35),
   optimizing the sequence of inspection tasks on the basis of the sequence of setting parameters of the multi-beam system (1) such that the number of changes in the setting parameters of the multi-beam system (1) is minimized.
Clause 10: Method according to Clause 1, wherein at least one previously known information item is considered when determining setting parameters, the previously known information item comprising at least one of a CAD information about a composition of the wafer (7) at an inspection position (33, 35), previous inspection tasks at adjacent inspection positions (33, 35) or a previous measurement or inspection at the inspection position (33, 35).
Clause 11: Method according to Clause 1, wherein the determination of setting parameters comprises the determination of a distance of the inspection position (33, 35) from an edge of the wafer (7).
Clause 12: Method according to any one of the preceding clauses, wherein the selected setting parameters comprise parameters of components within an illumination path (13) and within a detection path (11) of the multi-beam system (1), and comprise at least one of the following parameters:
   realigning the wafer (7) at the first inspection position (33, 35) using the displacement stage (500),
   driving correction electrodes for the purposes of influencing an extraction field (113) at the first inspection position (33, 35) at the surface (15) of the wafer (7),
   driving a deflection apparatus (107, 110) in the illumination path of the particle beams (3) for the purposes of compensating an offset of the raster arrangement (41) on the surface (25) of the wafer (7),
   changing a working point of the multi-beam system (1) for the purposes of adjusting a scale of the raster arrangement (41),
   changing a digital image evaluation.
Clause 13: Method for determining a complex multi-beam effect (41), comprising
   recording an image of a time-averaged inspection image of a raster arrangement (41) of the multiplicity of particle beams (3, 9) using a detector camera (207) by scanning a portion of a structured surface (25) of a wafer (7) and averaging out an image contrast of the surface structure of the wafer (7),
   analysing the inspection image for the purposes of determining at least one deviation of the raster arrangement (41) of the incidence locations (5, 15) of the plurality of particle beams from a predefined raster arrangement (41) and a change in a shape or a size of a focal point (5, 15) of the particle beams.
Clause 14: Method according to Clause 13, wherein an image contrast is averaged out by quickly scanning the portion of the surface (25) of the wafer (7) with an image recording time of T1<T2, such as less than T1<T2/10, for example T1<T/100, where T2 corresponds to the time for recording an image of the portion of the surface (25) with a high spatial resolution and a pixel dimension of 2 nm, 1 nm or less.
Clause 15: Method according to Clause 14, wherein T1 is less than 100 ms, such as less than 10 ms.
Clause 16: Method according to Clause 13, wherein the averaging out of the image contrast of the surface structure of the wafer (7) is implemented by averaging the detection signal over time.
Clause 17: Method according to any one of Clauses 13 to 16, wherein the deviation of the raster arrangement (41) comprises at least one of the following errors: a scale error (41a), an offset error (41b), a distortion (41c), a twist (41g), a local deviation (41d) of individual beams of the raster arrangement (41).
Clause 18: Method according to any one of Clauses 13 to 17, wherein the change in the shape or size of at least three focal points (5, 15) comprise at least one of the following aberrations: a constant astigmatism, a linear astigmatism with a linear profile of the astigmatism over the raster arrangement (41), a constant focal aberration, a linear focal aberration with a linear profile of the focal aberration over the raster arrangement (41).
Clause 19: Multi-beam system (1) having a plurality of primary particle beams (3) and a plurality of secondary particle beams (9), comprising
   a spatially resolving detector (207),
   at least one deflection system (110, 222) for deflecting the plurality of primary and secondary particle beams (3, 9) for the purposes of collective scanning of a portion of a structured surface (25) of a wafer (7),
   a control device (800) for driving the detector (207) and the deflection system (110, 222),
the control device (800) and the detector (207) being configured to capture a time-averaged inspection image of a raster arrangement (41) of the plurality of secondary particle beams (9) and/or to capture a digital image of the portion of the structured surface (25) with a spatial resolution of 2 nm, 1 nm or less.
Clause 20: Multi-beam system (1) according to Clause 19, wherein the control device (800) is configured, in a first mode of operation for capturing the time-averaged inspection image of the raster arrangement (41), to quickly scan a plurality of the primary particle beams (3) over the portion of the structured surface (25) of the wafer (7) in a time T1 using the deflection system (110) and, in a second mode of operation for recording the digital image of the portion of the structured surface (25), to slowly scan the plurality of primary particle beams (3) over the portion of the structured surface (25) of the wafer (7) in a time T2 using the deflection system (110), where T1<T2, such as T1<T2/10, for example T1<T2/100.
Clause 21: Multi-beam system (1) according to Clause 20, wherein the detector (207) contains a first detector (207a) and a second detector (207b) and the multi-beam system (1) comprises a detection unit (200) having a beam deflector (224) which is driven by the control unit (800) and configured to deflect during operation the plurality of secondary particle beams either onto the first detector (207a) or onto the second detector (207b).
Clause 22: Multi-beam system (1) according to Clause 21, wherein the beam deflector (224) is configured to keep during operation the plurality of secondary particle beams at a constant position either on the first detector (207a) or on the second detector (207b).
Clause 23: Multi-beam system according to Clause 19, wherein the detector (207) is designed for the simultaneous capture of the time-averaged inspection image of the raster arrangement (41) of the plurality of secondary particle beams (9) and of the digital image of the portion of the structured surface (25) with a high spatial resolution with a pixel dimension of 2 nm, 1 nm or less.
Clause 24: Multi-beam system according to Clause 23, wherein the detector (207) contains an electron conversion element which generates photons from electrons, and photons are detected simultaneously using a first, fast light detector for capturing a portion of the wafer surface (25) and a second, slow light detector for capturing the inspection image of the raster arrangement (41).
Clause 25: Multi-beam system (1) according to any of Clauses 19 to 24, wherein the control device (800) is further configured to determine a complex multi-beam effect consisting in a change in the incidence locations of the plurality of particle beams (3, 9) and a change in a shape or a size of focal points of the particle beams (3, 9) from the inspection image of the raster arrangement (41), and to derive and set changes in setting parameters of the multi-beam system (1) on the basis of the complex multi-beam effect.
Clause 26: Multi-beam system (1) according to Clause 25, wherein the control device (800) is connected to a plurality of components of an illumination path (13) and of a detection path (11), including components for setting a homogeneous extraction field (113) of the multi-beam system (1), and is configured to drive the setting parameters of the components of the illumination path (13) and of the detection path (11), including components for setting a homogeneous extraction field (113), for the purposes of reducing the complex multi-beam effect.
Clause 27: Multi-beam system (1) according to Clause 26, wherein the multi-beam system (1) further contains the following components that are connected to the control device (800) for driving purposes:
   a quasi-static deflector (107) for the plurality of primary particle beams (3),
   a dynamic deflector (110) for the scanning deflection of the primary particle beams (3) and secondary particle beams (9),
   a dynamic deflector (222, 224) for the scanning deflection of the secondary particle beams (9),
   electrostatic or magnetic lenses (306.2, 307, 103.2, 102) with a changeable focusing effect,
   a raster arrangement of multi-pole elements (306.2) for influencing the primary particle beams (3),
   correction electrodes 153 for setting a homogeneous extraction field (113) between the wafer surface 25 and a counter electrode 151 of an objective lens system 102 of the multi-beam system 1.
Clause 28: Multi-beam system (1) according to any of Clauses 19 to 27, further comprising:
   an electrical contacting of a counter electrode (151) below an objective lens (102) or a part of the objective lens (102) for supplying a first voltage difference V1 during operation,
   a displacement stage (500) with a reception area (505) for receiving and positioning a wafer (7) under the objective lens (102),
   an electrical contacting of the reception area (505) in order to apply a second voltage difference V2 to a wafer (7) during operation,
the displacement stage (500) further comprising at least one correction electrode (153) in the periphery of the reception area (505), with an electrical contact for supplying at least one third voltage difference V3 for the purposes of generating an extraction field (113) that is homogenous in an edge region of a wafer (7) during operation.
Clause 29: Multi-beam system (1) according to any of Clauses 19 to 28, wherein the control unit (800) further contains a unit (812) for image evaluation and the control unit (800) is configured to drive the unit for image evaluation (812) with a correction signal for the purposes of correcting at least a part of the complex multi-beam effect.
Clause 30: Wafer inspection multi-beam system (1) having a plurality of primary particle beams (3) and a plurality of secondary particle beams (9), comprising
   a displacement stage (500) for receiving a wafer (7),
   a spatially resolving detector (207),
   a first deflection system (110) for deflecting the plurality of primary particle beams (3) for the purposes of collective scanning the primary particle beams (3) over a portion of a structured surface (25) of the wafer (7),
   a second deflection system (222) for deflecting a plurality of secondary particle beams (9) in order to keep focal points (15) of the secondary particle beams (9) on the detector (207) constant,
   a control device (800),
   a plurality of components of an illumination path (13) and of a detection path (11), including components (151, 153, 505) for setting a homogeneous extraction field (113) of the multi-beam system (1),
the control device (800) being configured to acquire a list of inspection tasks at a plurality of inspection positions (33, 35) and to work through the list, the control device (800) further being configured to set setting parameters of the components of the illumination path (13) and of the detection path (11), including components (151, 153, 505) for setting the homogeneous extraction field (113), for the purposes of reducing a complex multi-beam effect at an inspection position (33, 35).
Clause 31: Multi-beam system (1) according to Clause 30, wherein the control unit (800) is further configured to detect the distance of an inspection position (33, 35) from an edge (43) of a wafer (7) and to compensate a complex multi-beam effect caused by a wafer edge (43).
Clause 32: Multi-beam system (1) according to either of Clauses 30 and 31, wherein the control unit (800) is further configured to determine the composition of a wafer (7) at an inspection position (33, 35) from CAD data prior to a measurement or inspection at the inspection position (33, 35), and to compensate (41) a complex multi-beam effect caused by the composition.
Clause 33: Multi-beam system (1) according to any of Clauses 30 to 32, wherein the control unit (800) further comprises a memory and is configured to determine stored parameters from stored inspection tasks at similar inspection sites and to set the stored parameters for the purposes of reducing a complex multi-beam effect at an inspection position (33, 35).
Clause 34: Multi-beam system (1) according to any of Clauses 30 to 33, wherein the control unit (800) further is configured to determine parameters from preceding inspection tasks at adjacent inspection sites and to set the parameters for the purposes of reducing a complex multi-beam effect at an inspection position (33, 35).
Clause 35: Multi-beam system (1) according to any of Clauses 30 to 34, wherein the control unit (800) is further configured to change a scanning program for driving the first and second deflection systems (110, 222) in order to at least partly compensate a complex multi-beam effect.
Clause 36: Multi-beam system (1) according to any of Clauses 30 to 35, wherein the control unit (800) is further configured to change a working point of the multi-beam system (1) in order to at least partly compensate a complex multi-beam effect.
Clause 37: Displacement stage (500) for a multi-beam microscope (1), comprising
   a reception area (505) for receiving a wafer (7) with an edge (43) and a diameter D, by which a voltage V2 can be applied to the wafer (7) during operation,
   a ring-shaped electrode (153) which is arranged in the periphery of the reception area (505) and which has an internal diameter DI>D such that, when a wafer (7) is received, a distance is formed between the edge (43) of the wafer (7) and the ring-shaped electrode (153),
   the electrode (153) being insulated from the reception area (505) so that a voltage V3 can be applied to the ring-shaped electrode (153) during operation.
Clause 38: Displacement stage (500) according to Clause 37, wherein the ring-shaped electrode (153) is formed from a plurality of mutually insulated electrode segments, for example two, four, eight or more, to which at least one first voltage V3 can be applied.
Clause 39: Multi-beam system (1) comprising a displacement stage (500) according to Clause 37 or 38.
Clause 40: Multi-beam system (1) according to Clause 39, wherein the multi-beam system (1) further comprises a control unit (503) which is configured to set the voltage V2 and the at least first voltage V3 for the purposes of generating a homogeneous extraction field during operation.
Clause 41: Method of setting a multi-beam system (1) for inspecting a wafer (7), including the following steps:
   recording an image of a time-averaged first reference image of a raster arrangement 41 of a plurality of particle beams using a detector camera 207 by quickly scanning a reference position on a wafer 7 within a first time T1;
   homing in on an inspection position (33, 35);
   recording an image of a time-averaged first inspection image of the raster arrangement 41 of the plurality of particle beams at an inspection position (33, 35) using the detector camera 207 by quickly scanning the inspection position (33, 35) within the first time T1;
   analysing the first inspection image of the raster arrangement (41) and the first reference image of the raster arrangement (41) and deriving selected setting parameters for adjusting the multi-beam system (1) for the purposes of optimal imaging at the inspection site (33, 35);
   setting the multi-beam system (1) using the selected setting parameters;
   recording an inspection image of the surface (25) of the wafer (7) with a high spatial resolution by slow scanning of the inspection position (33, 35) in a second time T2, where T1<T2, such as T1<T2/10, for example T1<T2/100.
Clause 42: Method according to Clause 41, further including recording an image of a time-averaged second reference image of the raster arrangement (41) of the plurality of primary beams using the detector camera (207) by quickly scanning the reference position within the first time T1 after setting the multi-beam system (1) with the selected setting parameters.
Clause 43: Method according to Clause 41, further including recording an image of a time-averaged second inspection image of the raster arrangement (41) of the plurality of primary beams using the detector camera (207) by quickly scanning the inspection position (33, 35) within the first time T1 and checking the setting of the multi-beam system (1) with the selected setting parameters.
Clause 44: Method according to any one of Clauses 41 to 43, wherein the selected setting parameters comprise at least one of the following parameters:
   realignment of the wafer (7) using a displacement stage (500);
   driving electrodes (151, 153, 505) for influencing a field profile of an extraction field 113 at the surface 25 of the wafer 7;
   driving a beam deflector (107, 110, 222) for compensating an offset of the raster arrangement (41);
   changing a working point of the multi-beam system for the purposes of adjusting a scale of the raster arrangement 41;
   changing a digital image evaluation.
Clause 45: Method according to any one of Clauses 41 to 44, further including assigning the selected setting parameters to the inspection position (33, 35) and storing of the assignment.
Clause 46: Method according to Clause 45, further comprising a repeated inspection of at least a second wafer (7) at the inspection position (33, 35) using the stored setting parameters assigned to the inspection position (33, 35).
Clause 47: Method according to any one of Clauses 41 to 46, wherein the reference position corresponds to a preceding inspection position (33, 35).
Clause 48: Method according to any one of clause 41 to 46, wherein the reference position corresponds to a position on a reference object.
Clause 49: Wafer inspection method using a multi-beam system (1), including the following steps:
a. homing in on an inspection position on a wafer (7);
b. on the basis of the inspection position, determining setting parameters of the multi-beam microscope (1), determined in advance, for optimal imaging at the inspection position;
c. setting the determined setting parameters,
d. recording an image of a portion of the surface (25) of the wafer (7) at the inspection position.
Clause 50: Method according to Clause 49, further including:
   loading predefined setting parameters of the multi-beam microscope which are assigned to the inspection position;
   interpolating the setting parameters for optimal imaging at the inspection position from at least two setting parameters which are assigned to two adjacent inspection positions.
Clause 51: Method according to clause 49, further including:
   determining a priori information about the inspection position, the a priori information including at least one of the following information items:
   distance of the inspection position from an edge (43) of the wafer (7),
   CAD information about the material composition at the surface (25) of the wafer (7) at the inspection position,
   distance of the inspection position from preceding image recordings at preceding inspection positions.
Clause 52: Method according to any of clauses 49 to 51, wherein the setting parameters comprise voltage values for generating a homogeneous extraction field (143) at the surface (25) of the wafer (7) at the inspection position, and the voltage values are supplied to the electrodes (151 153, 505).

### LIST OF REFERENCE SIGNS USED

1 Multi-beam system
3 Primary beams or plurality of primary beams
5 Focal points of the primary beams
7 Wafer
9 Secondary beams
11 Detection beam path
13 Illumination path
15 Focal points of the secondary beams
17 Image field
21 Centre of an image field and centre of an inspection position
25 Wafer surface
27 Scanning path of a primary beam
29 Centre of a sub-field
31 Sub-fields
33 First inspection position
34 Second inspection position
35 Third inspection position
41 Raster arrangement
43 Edge of the wafer
47 Distance of an inspection position from the wafer edge
61 Local displacement of a spot position
100 Illumination system
101 Object plane or first plane
102 Objective lens system
103 Field lenses
105 Optical axis of the objective lens
107 Quasi-static deflector
108 Crossover point
110 Scanning deflector
113 Extraction field
130 Slow compensators of the illumination system
132 Fast compensators of the illumination system
149 Coils of a magnetic lens
151 Counter electrode
153 Ring-shaped correction electrode
155 Insulation
200 Detection system with detection path for imaging the secondary electrons
205 Projection lens
206 Electrostatic lens
207 Spatially resolving particle detector
208 Magnetic lens
209 Magnetic lens
210 Projection lens
212 Crossover point of the secondary beams
214 Aperture stop or contrast stop
216 Multi-aperture plate
218 Third deflection system
222 Second deflection system
224 Second deflection system with switchover between projection system 205a and 205b
230 Slow compensators of the detection system
232 Fast compensators of the detection system
238 Sensors
280 Image data converter
300 Beam generation device
301 Electron source
303 Collimation lenses
305 Multi-aperture arrangement
306 Multi-aperture plate
307 Field lens
308 Field lens
309 Particle beam
311 Beam focal points in the intermediate image plane
321 Intermediate image plane
330 Slow compensators of the multi-beam generation device
332 Fast compensators of the multi-beam generation device
390 Deflector array
400 Beam divider
420 Correction element of the beam divider
500 Displacement stage
503 Voltage supply for the object voltage
505 Object reception area
520 Position sensors of the displacement stage
800 Control unit
810 Data acquisition device
812 Digital image processing unit
814 Image data memory
818 Sensor data module
820 Control module for the detection system
830 Control unit of the illumination device
840 Control processor
860 Scanning module
880 Control module of the displacement stage
903 Existing charge from preceding inspection tasks
905 Increasing charge during an inspection task
907 Dynamically changeable parameter for driving the multi-beam system during an inspection task

What is claimed is:

1. A multi-beam system configured to provide a plurality of primary particle beams and a plurality of secondary particle beams, the multi-beam system comprising:
a spatially resolving detector;
a deflection system configured to deflect the primary and secondary particle beams to collectively scan of a portion of a structured surface of a wafer; and
a control device configured to drive the spatially resolving detector and the deflection system,
wherein the control device and the spatially resolving detector are configured to capture: i) a time-averaged inspection image of a raster arrangement of the plurality of secondary particle beams with a spatial resolution of two nanometers or less; and/or ii) a digital image of the portion of the structured surface with a spatial resolution of two nanometers or less.

2. The multi-beam system of claim 1, wherein:
in a first mode of operation, the control device is configured to: i) capture the time-averaged inspection image of the raster arrangement; and ii) scan the primary particle beams over the portion of the structured surface of the wafer in a time T1 using the deflection system;
in a second mode of operation, the control device is configured to: i) record the digital image of the portion of the structured surface of the wafter; and ii) to scan the primary particle beams over the portion of the structured surface of the wafer in a time T2 using the deflection system; and
T1<T2.

3. The multi-beam system of claim 2, wherein:
the spatially resolving detector comprises first and second detectors;
the multi-beam system further comprises a detection unit comprising a beam deflector;
the control unit is configured to drive the beam deflector; and
the beam deflector is configured to deflect the secondary particle beams onto a member selected from the group consisting of the first detector and the second detector.

4. The multi-beam system of claim 3, wherein the beam deflector is configured to keep the secondary particle beams at a constant position on the member.

5. The multi-beam system of claim 1, wherein the spatially resolving detector is configured to simultaneously capture: i) the time-averaged inspection image of the raster arrangement of the secondary particle beams; and ii) the digital image of the portion of the structured surface with a spatial resolution with a pixel dimension of two nanometers or less.

6. The multi-beam system of claim 6, wherein:
the spatially resolving detector further comprises an electron conversion element, a first light detector and a second light detector;
the electron conversion element is configured to generate photons from electrons;
the first light detector is configured to detect some of the photons to capture for a portion of the wafer surface;
the second light detector is configured to detect some of the photons to capture the time-averaged inspection image of the raster arrangement; and
the first light detector is faster than the second light detector.

7. The multi-beam system of claim 1, wherein the control device is further configured to: a) determine a change in incidence locations of the first and second particle beams; b) determine a change in a shape or a size of focal points of the first and second particle beams from the time-averaged inspection image of the raster arrangement; and d) derive and set changes in setting parameters of the multi-beam system on the basis of a) and b).

8. The multi-beam system of claim 7, further comprising a plurality of components of an illumination path and of a detection path, wherein:
the components are connected to the control device;
the components comprise components configured to set a homogeneous extraction field of the multi-beam system; and
the control device is configured to drive setting parameters of the components to reduce effects of a) and b).

9. The multi-beam system of claim 8, further comprising the following components each of which is connected to the control device so that he control device drives the component:
a quasi-static deflector configured to deflect the primary particle beams;
a first dynamic deflector configured to scanningly deflect the primary beams;
a second dynamic deflector configured to scanningly deflect the secondary particle beams;
electrostatic or magnetic lenses having a changeable focusing effect;
a raster arrangement of multi-pole elements configured to influence the primary particle beams; and
correction electrodes configured to set a homogeneous extraction field between the wafer surface and a counter electrode of an objective lens system of the multi-beam system.

10. The multi-beam system of claim 7, wherein the control unit further comprises a unit configured to evaluate an image, and the control unit is configured to drive the unit to evaluate the image with a correction signal to at least partially correct a complex multi-beam effect.

11. The multi-beam system of claim 1, further comprising:
a first electrical contacting of a counter electrode at least partially below an objective lens to supply a first voltage difference;
a displacement stage comprising a reception area configured to receive and position the wafter under the objective lens;
a second electrical contacting of the reception area to apply a second voltage difference to the wafer,
wherein:
the displacement stage further comprises a correction electrode in a periphery of the reception area;
the correction electrode comprises an electrical contact configured to supply at least a third voltage difference to generate an extraction field that is homogenous in an edge region of the wafer.

12. A wafer inspection multi-beam system configured to provide a plurality of primary particle beams and a plurality of secondary particle beams, the wafer inspection multi-beam system, comprising:
a displacement stage configured to receive a wafer;
a spatially resolving detector;
a first deflection system configured to deflect the primary particle beams to collectively scan the primary particle beams over a portion of a structured surface of the wafer;
a second deflection system configured to deflect the secondary particle beams to keep focal points of the secondary particle beams on the spatially resolving detector constant;
a control device; and
a plurality of components of an illumination path and of a detection path, the components comprising components configured to set a homogeneous extraction field of the multi-beam system,
wherein the control device is configured to:
acquire a list of inspection tasks at a plurality of inspection positions work through the list; and
set setting parameters of the components of the illumination path to reduce a complex multi-beam effect at an inspection position.

13. The wafer inspection multi-beam system of claim 12, wherein the control unit is configured to detect a distance of an inspection position from an edge of the wafer, and the control unit is configured to compensate a complex multi-beam effect caused by the wafer edge.

14. The wafer inspection multi-beam system of claim 12, wherein the control unit is configured to determine a composition of the wafer at an inspection position from CAD data prior to a measurement or inspection at the inspection position, and the control unit is configured to compensate a complex multi-beam effect caused by the composition.

15. The wafer inspection multi-beam system of claim 12, wherein the control unit further comprises a memory, the control unit is configured is configured to determine stored parameters from stored inspection tasks at similar inspection sites, and the control unit is configured to set the stored parameters to reduce a complex multi-beam effect at an inspection position.

16. The wafer inspection multi-beam system of claim 12, wherein the control unit is configured to determine parameters from preceding inspection tasks at adjacent inspection sites, and the control unit is configured to set the parameters to reduce a complex multi-beam effect at an inspection position.

17. The wafer inspection multi-beam system of claim 12, wherein the control unit is configured to change a scanning program for driving the first and second deflection systems to at least partly compensate a complex multi-beam effect.

18. The wafer inspection multi-beam system of claim 12, wherein the control unit is configured to change a working point of the multi-beam system to at least partly compensate a complex multi-beam effect.

19. A method of setting a multi-beam system to inspect a wafer, the method comprising:
recording an image of a time-averaged first reference image of a raster arrangement of a plurality of particle beams using a detector camera by scanning a reference position on a wafer within a first time;
homing in on an inspection position;
recording an image of a time-averaged first inspection image of the raster arrangement of the plurality of particle beams at an inspection position using the detector camera by quickly scanning the inspection position within the first time;
analyzing the first inspection image of the raster arrangement and the first reference image of the raster arrangement and deriving selected setting parameters for adjusting the multi-beam system for improved imaging at the inspection site;
setting the multi-beam system using the selected setting parameters;
recording an inspection image of the surface of the wafer with a spatial resolution by slow scanning of the inspection position in a second time which is greater than the first time.

20. The method of claim 19, further comprising recording an image of a time-averaged second reference image of the raster arrangement of the plurality of primary beams using the detector camera by scanning the reference position within the first time after setting the multi-beam system with the selected setting parameters.

21. The method of claim 19, further comprising recording an image of a time-averaged second inspection image of the raster arrangement of the plurality of primary beams using the detector camera by scanning the inspection position within the first time T1 and checking the setting of the multi-beam system with the selected setting parameters.

22. The method of claim 19, wherein the selected setting parameters comprise at least one member selected from the group consisting of: realignment of the wafer using a displacement stage; driving electrodes for influencing a field profile of an extraction field at the surface of the wafer; driving a beam deflector to compensate an offset of the raster arrangement; changing a working point of the multi-beam system for the purposes of adjusting a scale of the raster arrangement; and changing a digital image evaluation.

23. The method of claim 19, further comprising assigning the selected setting parameters to the inspection position and storing of the assignment.

24. The method of claim 23, further comprising inspecting a second wafer at the inspection position using stored setting parameters assigned to the inspection position.

25. The method of claim 19, wherein the reference position corresponds to a preceding inspection position.

26. The method of claim 19, wherein the reference position corresponds to a position on a reference object.

27. A method, comprising:
homing in on an inspection position on a wafer;
based on the inspection position, determining setting parameters of a multi-beam microscope to image at the inspection position;
setting the determined setting parameters; and
based on the set parameters, using the multi-beam microscope to record an image of a portion of the surface of the wafer at the inspection position.

28. The method of claim 27, further comprising:
loading predefined setting parameters of the multi-beam microscope which are assigned to the inspection position; and
interpolating the setting parameters for optimal imaging at the inspection position from at least two setting parameters which are assigned to two adjacent inspection positions.

29. The method of claim 28, further comprising:
determining a priori information about the inspection position, the a priori information including at least one member selected from the group consisting of: a distance of the inspection position from an edge of wafer; CAD information about the material composition at the surface of the wafer at the inspection position; and a distance of the inspection position from preceding image recordings at preceding inspection positions.

30. The method of claim 27, wherein the setting parameters comprise voltage values to generate a homogeneous extraction field at the surface of the wafer at the inspection position, and the method further comprises supplying the voltage values to the electrodes.
